(19) United States
(12) Patent Application Publication
(10) Pub. No.: US 2026/0293494 A1
(43) Pub. Date: Sep. 24, 2026

(54) DISPLAY PANEL, METHOD OF MANUFACTURING THE DISPLAY PANEL, AND ELECTRONIC DEVICE INCLUDING THE DISPLAY PANEL

(71) Applicant: Samsung Display Co., Ltd., Yongin-si (KR)

(72) Inventor: Sungsik Yun, Yongin-si (KR)

(21) Appl. No.: 19/405,235

(22) Filed: Dec. 1, 2025

(30) Foreign Application Priority Data
Mar. 20, 2025 (KR) 10-2025-0036214

(51) Int. Cl. H10K 59/80; H10K 59/12; H10K 59/122

(52) U.S. Cl. CPC H10K 59/873; H10K 59/1201; H10K 59/122

(57) ABSTRACT

A display panel includes: a substrate including an opening area, an intermediate area at least partially surrounding around the opening area, and a display area at least partially surrounding around the intermediate area; a light-emitting diode in the display area; a first dam in the intermediate area, and having at least one first groove defined in an upper surface of the first dam; and a second dam between the first dam and the display area, the second dam including: an organic material portion; and a metal portion within the organic material portion, and having a portion protruding beyond a side surface of the organic material portion.

### CROSS-REFERENCE TO RELATED APPLICATION

The present application claims priority to and the benefit of Korean Patent Application No. 10-2025-0036214, filed on Mar. 20, 2025, in the Korean Intellectual Property Office, the entire disclosure of which is incorporated by reference herein.

### BACKGROUND

### 1. Field

Aspects of embodiments of the present disclosure relate to a display panel, a method of manufacturing the display panel, and an electronic device including the display panel.

### 2. Description of the Related Art

An electronic device may display images and/or videos by using a display panel provided in the electronic device. In recent years, as uses of display panels have diversified, various functions that may be embedded in or linked to display panels are being proposed. Various methods have been proposed to ensure basic functions of a display panel on which images are realized, while adding various functions.

In addition to a display panel, an electronic device may include a component for performing other functions. For example, an electronic device may include other components, such as cameras or sensors. The components may be disposed on a surface (e.g., on a rear surface) of the display panel. In order for the components to perform their functions smoothly, an opening area may be defined in the display panel in an area overlapping with the component. The opening may be defined through the display panel. The opening defined in the display panel may be implemented by forming a plurality of layers on a substrate, cutting the plurality of layers and the substrate, and removing a portion corresponding to the opening.

The above information disclosed in this Background section is for enhancement of understanding of the background of the present disclosure, and therefore, it may contain information that does not constitute prior art.

### SUMMARY

In a process of cutting a substrate and a plurality of layers on the substrate along a cutting line, and removing a portion corresponding to an opening so as to form an opening in a display panel, a delamination may occur between some of the plurality of layers on the substrate. As such, a structure may be desired to prevent or substantially prevent the delamination.

Embodiments of the present disclosure may be directed to a display panel in which a delamination of layers therein may be prevented or substantially prevented, a method of manufacturing the display panel, and an electronic device including the display panel.

However, the present disclosure is not limited to the above aspects and features. The above and additional aspects and features will be set forth, in part, in the description that follows, and in part, may be apparent from the description, or may be learned by practicing one or more of the presented embodiments of the present disclosure.

According to one or more embodiments of the present disclosure, a display panel includes: a substrate including an opening area, an intermediate area at least partially surrounding around the opening area, and a display area at least partially surrounding around the intermediate area; a light-emitting diode in the display area; a first dam in the intermediate area, and having at least one first groove defined in an upper surface of the first dam; and a second dam between the first dam and the display area, the second dam including: an organic material portion; and a metal portion within the organic material portion, and having a portion protruding beyond a side surface of the organic material portion.

In an embodiment, the display panel may further include an inorganic encapsulation layer on the first dam and the second dam.

In an embodiment, the inorganic encapsulation layer may include a first portion and a second portion overlapping with a first edge and second edge, respectively, of the first dam defining the at least one first groove, and the first portion and the second portion of the inorganic encapsulation layer may be in contact with each other.

In an embodiment, the inorganic encapsulation layer may integrally extend and cover an upper surface, a side surface, and a lower surface of the metal portion protruding beyond the side surface of the organic material portion.

In an embodiment, a portion of a lower surface of the inorganic encapsulation layer located on the first dam may be spaced from a portion of an upper surface of the first dam.

In an embodiment, the first dam may include a plurality of first dams, and the display panel may further include, on the inorganic encapsulation layer, an organic encapsulation layer having at least a portion located between two adjacent first dams of the plurality of first dams.

In an embodiment, a width of the first groove of the first dam may be about 1.5 to about 2 times a thickness of the inorganic encapsulation layer on the first dam.

In an embodiment, in a plan view, the first dam may surround around the opening area.

In an embodiment, an opening overlapping with the opening area may be defined in the substrate.

According to one or more embodiments of the present disclosure, a method of manufacturing a display panel includes: preparing a substrate in which an opening area, an intermediate area at least partially surrounding around the opening area, and a display area at least partially surrounding around the intermediate area are defined; placing, in the intermediate area, a first dam having at least one first groove defined in an upper surface of the first dam; placing an inorganic encapsulation layer on the first dam, a first portion and a second portion of the inorganic encapsulation layer overlapping with a first edge and a second edge, respectively, of the first dam defining the at least one first groove being in contact with each other in an area overlapping with the at least one first groove; and cutting the substrate along a boundary between the intermediate area and the opening area.

In an embodiment, the method may further include placing, between the first dam and the display area, a second dam including: an organic material portion; and a metal portion disposed within the organic material portion, and protruding beyond a side surface of the organic material portion.

In an embodiment, the inorganic encapsulation layer may be disposed on the second dam, and may integrally extend and cover an upper surface, a side surface, and a lower surface of a portion of the metal portion protruding beyond the side surface of the organic material portion of the second dam.

In an embodiment, in the cutting of the substrate, a portion of a lower surface of the inorganic encapsulation layer located on the first dam may be spaced from a portion of an upper surface of the first dam.

In an embodiment, the first dam may include a plurality of first dams, and the method may further include placing an organic encapsulation layer on the inorganic encapsulation layer, at least a portion of the organic encapsulation layer being located between two adjacent first dams of the plurality of first dams.

In an embodiment, the method may further include placing, in the opening area, an inner dam having at least one second groove defined in an upper surface of the inner dam.

In an embodiment, a cross-sectional shape of the at least one first groove of the first dam and a cross-sectional shape of the at least one second groove of the inner dam may be same as each other.

In an embodiment, the inorganic encapsulation layer may be disposed on the inner dam, and may include a third portion and a fourth portion overlapping with a first edge and a second edge, respectively, of the inner dam defining the at least one second groove, and the third portion and the fourth portion of the inorganic encapsulation layer may be in contact with each other in an area overlapping with the at least one second groove.

In an embodiment, the method may further include removing a portion of the substrate corresponding to the opening area together with the inner dam.

In an embodiment, the inorganic encapsulation layer may extend across the display area, the intermediate area, and the opening area, and the inorganic encapsulation layer may be cut together with the substrate in the cutting of the substrate.

According to one or more embodiments of the present disclosure, an electronic device includes: a display panel; and a processor configured to drive the display panel. The display panel includes: a substrate including an opening area, an intermediate area at least partially surrounding around the opening area, and a display area at least partially surrounding around the intermediate area; a light-emitting diode in the display area; a first dam in the intermediate area, and having at least one first groove defined in an upper surface of the first dam; and an inorganic encapsulation layer covering the light-emitting diode and the first dam. The inorganic encapsulation layer includes a first portion and a second portion overlapping with a first edge and second edge, respectively, of the first dam defining the at least one first groove. The first portion and the second portion of the inorganic encapsulation layer are in contact with each other.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a block diagram of an electronic device according to an embodiment;

FIGS. 2-4 are schematic diagrams of some electronic devices according to some embodiments;

FIG. 5 is a plan view of a display panel according to an embodiment;

FIG. 6 is a plan view of a display panel according to an embodiment;

FIG. 7 is a plan view of a display panel according to an embodiment;

FIG. 8 is a schematic cross-sectional view of a display panel according to an embodiment;

FIGS. 9-11 are each an equivalent circuit diagram of a pixel of a display panel according to an embodiment;

FIG. 12 is a cross-sectional view of a display area of a display panel according to an embodiment;

FIG. 13 is a plan view of a display panel according to an embodiment;

FIG. 14 is a cross-sectional view of a display panel according to an embodiment;

FIG. 15 is an enlarged cross-sectional view of a display panel according to an embodiment;

FIG. 16 is a cross-sectional view of a display panel according to an embodiment;

FIG. 17 is a cross-sectional view of a display panel according to an embodiment; and

FIGS. 18A-18G are cross-sectional views illustrating various processes of a method of manufacturing a display panel according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

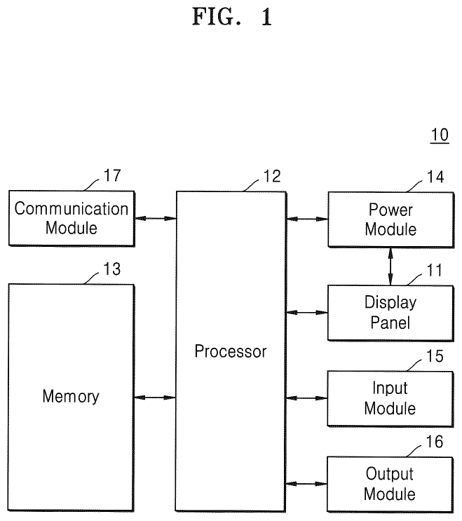

FIG. 1 is a block diagram of an electronic device according to an embodiment.

Referring to FIG. 1, an electronic device 10 may include a display panel 11, a processor 12, a memory 13, and a power module (e.g., a power supply circuit or a power supply) 14.

The processor 12 may include at least one of a central processing unit (CPU), an application processor (AP), a graphics processing unit (GPU), a communication processor (CP), an image signal processor (ISP), and/or a controller. In an embodiment, the processor 12 may be provided by being partitioned into two portions from a functional or structural standpoint. For example, the processor 12 may include a main processor in the form of a first driving chip including a CPU, and an auxiliary processor in the form of a second driving chip including a controller that receives an image signal from the main processor and processes the image signal to match an interface specification of the display panel 11.

The memory 13 may include at least one of a non-volatile memory and/or a volatile memory. The memory 13 may store data information used for an operation of the processor 12 or the display panel 11. The processor 12, when executing an application stored in the memory 13, may transfer an image data signal and/or an input control signal to the display panel 11, and may process the signal received by the display panel 11 to output image information through a display screen.

The power module 14 may include a power supply module, such as a power adapter or a battery device, and a power conversion module that converts power supplied by the power supply module to generate power used for operations of the electronic device 10. Power conversion by the power conversion module may include a direct current (DC)-DC conversion, an alternating current (AC)-DC conversion, and/or a DC-AC conversion, but the present disclosure is not limited thereto.

The electronic device 10 may further include an input module 15, a non-video output module 16, and/or a communication module 17.

The input module 15 may provide input information to the processor 12 and/or the display panel 11. The input module 15 may include various suitable sensor modules (e.g., sensors), as well as physical buttons, a keyboard, and a microphone. Examples of the sensor modules may include biosensors, such as blood pressure sensors, blood sugar sensors, electrocardiogram sensors, or heart rate sensors, as well as touch sensors, pressure sensors, distance sensors, location sensors, digitizers, motion recognition sensors, camera sensors, photodetectors, photoelectric conversion sensors, or temperature sensors.

The non-video output module 16 may receive information other than an image from the processor 12, and may provide the information to a user. Examples of the non-video output module 16 may include an audio module, a haptic module, a light-emitting module, and other suitable functional modules unique to the electronic device (e.g., a cooling module of a refrigerator).

The communication module 17 may be responsible for transmission and reception of information between the electronic device 10 and an external device, and may include a reception unit and a transmission unit. The communication module 17 may include various suitable wireless communication modules, such as a mobile communication module, a wireless fidelity (Wi-Fi) module, or a Bluetooth module, and/or various suitable wired communication modules.

At least one of the elements of the electronic device 10 described above may be included within a display device. In addition, some of individual modules functionally included in a single module may be included within the display device, and others may be provided separately from the display device. For example, the display device may include the display panel 11, and the processor 12, the memory 13, and the power module 14 may be provided in the form of other devices within the electronic device 10 rather than the display device. As another example, the power module 14 may be provided within the display device, and may supply power to the processor 12 and the memory 13 provided within the electronic device 10 rather than the display device. However, the present disclosure is not limited thereto.

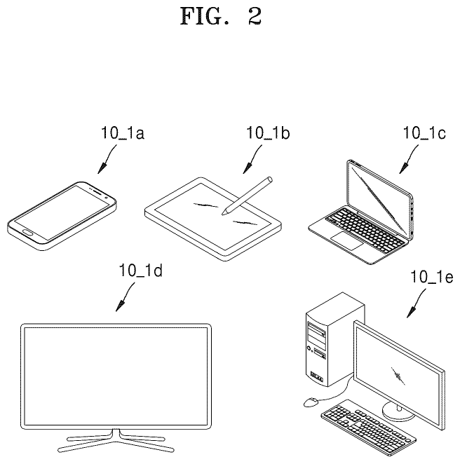

FIGS. 2 through 4 are schematic diagrams of some electronic devices according to some embodiments. FIGS. 2 to 4 show various examples of some electronic devices to which display devices according to some embodiments may be applied.

FIG. 2 shows examples of some electronic devices, such as a smartphone 10_1a, a tablet personal computer (PC) 10_1b, a laptop 10_1c, a television (TV) 10_1d, and a desk monitor 10_1e.

In addition to a display panel, the smartphone 10_1a may include an input module, such as a touch sensor, and a communication module. The smartphone 10_1a may process information received via the communication module or another input module, and may display information via the display panel of the display device.

Similar to the smartphone 10_1a, the tablet PC 10_1b, the laptop 10_1c, the TV 10_1d, the desk monitor 10_1e may include a display panel and an input module, and may further include a communication module in some cases.

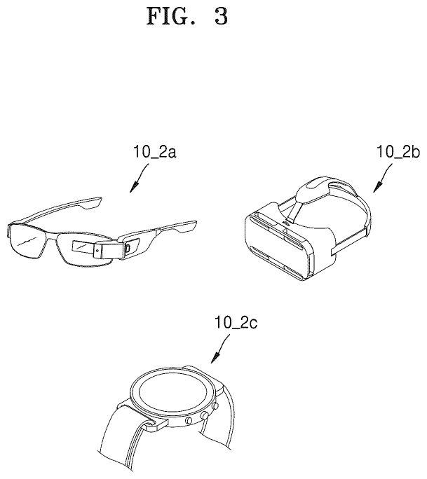

FIG. 3 shows examples in which an electronic device including a display panel is applied to a wearable electronic device. The wearable electronic device may include smart glasses 10_2a, a head-mounted display 10_2b, a smart watch 10_2c, or the like.

The smart glasses 10_2a and the head-mounted display 10_2b may include a display panel that emits a display image or screen, and a reflector that reflects the emitted display screen to provide the reflected display screen to a user's eyes. Accordingly, a virtual reality screen or an augmented reality screen may be provided to the user.

The smart watch 10_2c may include a biometric sensor as an input device, and may provide biometric information recognized through the biometric sensor to the user through the display screen.

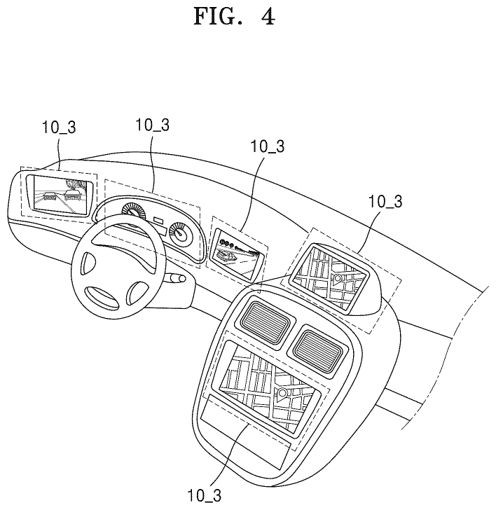

FIG. 4 shows an example in which an electronic device including a display panel is applied to a vehicle. For example, an electronic device 10_3 may be applied to an instrument panel of a vehicle or a center fascia, or may be applied to a center information display (CID) disposed on a dashboard of a vehicle or a room mirror display that replaces side-view mirrors.

In some other embodiments, an electronic device to which a display device is applied may include not only devices that mainly display screens, such as billboards, electronic boards, or game consoles, but may also include various suitable home appliances that display information through a display panel, such as refrigerators, washing machines, dryers, air conditioners, or robot vacuum cleaners. In addition, when the display panel has a function of transmitting light, the display panel may be applied to various suitable electronic devices, such as smart windows or transparent display devices that display a background and a display image together. The kinds of electronic devices are not limited to those described above, and various other suitable applications of electronic devices not described above may also be implemented according to some embodiments of the present disclosure.

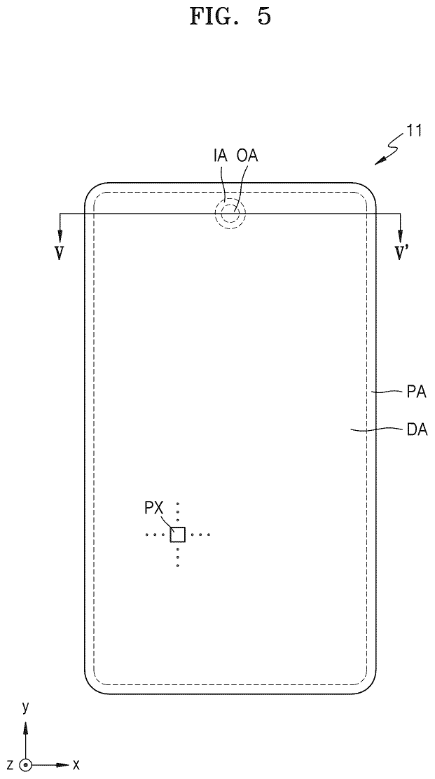

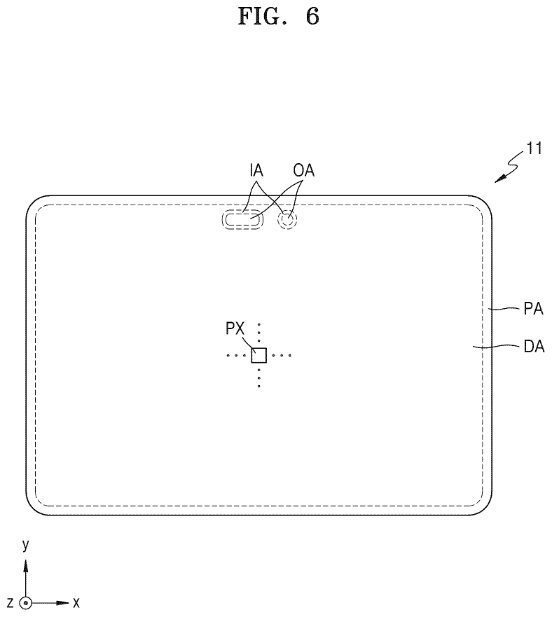

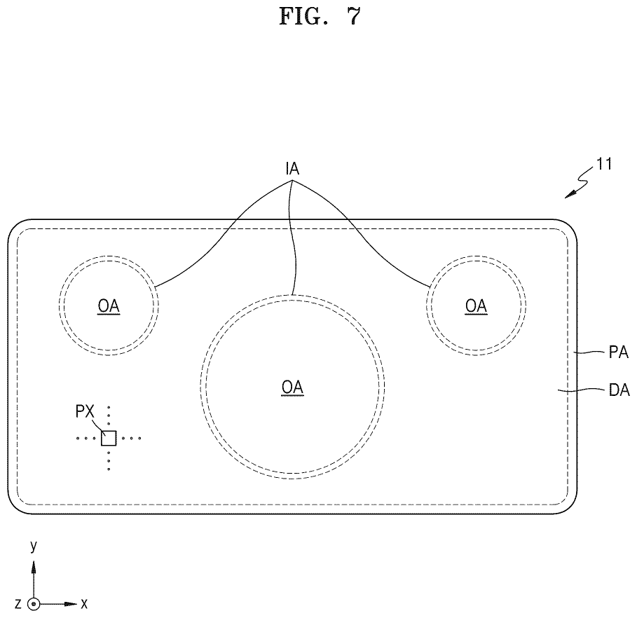

FIG. 5 is a plan view of a display panel according to an embodiment. FIG. 6 is a plan view of a display panel according to an embodiment. FIG. 7 is a plan view of a display panel according to an embodiment.

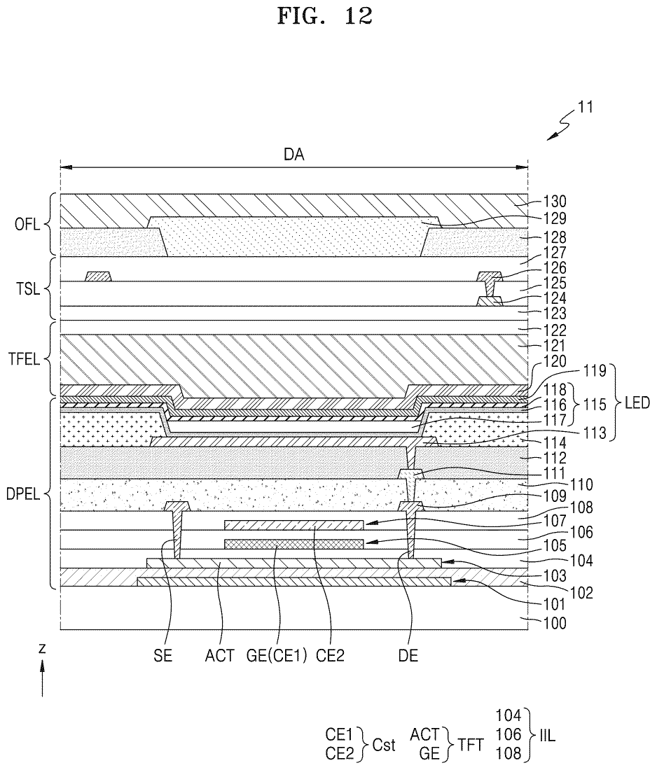

Referring to FIGS. 5 to 7, the display panel 11 may include a display area DA, a peripheral area PA, an opening area OA, and an intermediate area IA. The display area DA, the peripheral area PA, the opening area OA, and the intermediate area IA may be defined on the display panel 11. In other words, the display panel 11 may include a substrate 100 (e.g., see FIG. 12), and the display area DA, the peripheral area PA, the opening area OA, and the intermediate area IA may be defined on or included in the substrate 100.

In an embodiment, the peripheral area PA may at least partially or entirely surround (e.g., around a periphery of) the display area DA. In an embodiment, the display area DA may at least partially or entirely surround (e.g., around a periphery of) the intermediate area IA. In an embodiment, the intermediate area IA may at least partially or entirely surround (e.g., around a periphery of) the opening area OA. In an embodiment, the intermediate area IA may be disposed between the display area DA and the opening area OA.

In an embodiment, the opening area OA may be located inside the display area DA. In an embodiment, as shown in FIGS. 5 and 6, the opening area OA may be disposed in an upper center of the display area DA. In an embodiment, as shown in FIGS. 6 and 7, the opening area OA may be provided in a plurality. In an embodiment, as shown in FIG. 6, the plurality of opening areas OA may differ in shape from each other. In an embodiment, as shown in FIG. 7, the plurality of opening areas OA may have the same or substantially the same shape (e.g., a circle) as each other, but may differ in a size (e.g., a dimension) from each other. In an embodiment, as shown in FIG. 7, the plurality of opening areas OA may be disposed in a central portion of the display area DA. A shape, size, and arrangement of the opening area OA are not limited to those illustrated in FIGS. 5 to 7, and may be variously modified as needed or desired.

In an embodiment, an image may be displayed on the display panel 11 through a plurality of pixels PX disposed in the display area DA. The plurality of pixels PX of the display panel 11 may include a light-emitting diode as a display element for displaying images, and a pixel circuit for driving the light-emitting diode.

In an embodiment, the display panel 11 may have an approximately rectangular shape in a plan view. In an embodiment, as shown in FIG. 5, the display panel 11 may have a rectangular planar shape having a short side extending in the x direction, and a long side extending in the y direction. The rectangular shape may have rounded corners. In an embodiment, as shown in FIGS. 6 and 7, the display panel 11 may have a rectangular planar shape having a long side extending in the x direction, and a short side extending in the y direction, and may have rounded corners. However, the display panel 11 according to one or more embodiments is not limited to such shapes, and may be provided in other suitable polygonal shapes, an elliptical shape, or an irregular shape. In addition, the display panel 11 may also be stretchable, so that the display panel 11 may be bent depending on a shape of the electronic device 10 to which the display panel 11 is applied, or a space in which the display panel 11 is disposed.

In an embodiment, the display panel 11 shown in FIG. 5 may be applied to the electronic device 10, such as the smartphone 10_1a (e.g., see FIG. 2). In an embodiment, the display panel 11 shown in FIG. 6 may be applied to the electronic device 10, such as the tablet PC 10_1b, the laptop 10_1c, the TV 10_1d, or the desk monitor 10_1e (e.g., see FIG. 2). In an embodiment, the display panel 11 shown in FIG. 7 may be applied to the electronic device 10, such as the electronic device 10_3 for a vehicle. In an embodiment, when the display panel 11 is applied to the electronic device 10_3 for a vehicle, the display panel 11 may be provided in a curved shape corresponding to, for example, a curved surface of the electronic device 10_3 for a vehicle, or a curved space (or surface) inside a vehicle where the display panel 11 is disposed. In an embodiment, when the display panel 11 is applied to the electronic device 10_3 for a vehicle, the opening area OA of the display panel 11 may correspond to an area where other elements (e.g., electronic elements) of the electronic device 10_3 for a vehicle are disposed.

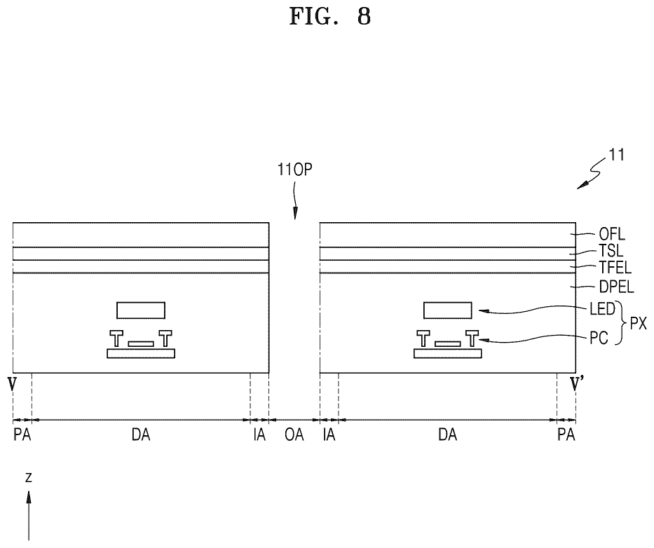

FIG. 8 is a schematic cross-sectional view of a display panel according to an embodiment. FIG. 8 is a cross-sectional view taken across the intermediate area IA and the opening area OA of the display panel 11. For example, FIG. 8 is a cross-sectional view of the display panel 11 taken along the line V-V′ in FIG. 5.

Referring to FIG. 8, the display panel 11 may include a display element layer DPEL, a thin-film encapsulation layer TFEL, a touch sensing layer TSL, and an optical functional layer OFL.

The display element layer DPEL may include the plurality of pixels PX. The pixel PX may include a light-emitting diode LED, and a pixel circuit PC to drive the light-emitting diode LED. The display element layer DPEL may include elements included in the light-emitting diode LED and/or pixel circuit PC that are arranged in a plurality of layers. In an embodiment, the light-emitting diode LED may be an organic light-emitting diode including an organic emission layer. In an embodiment, the light-emitting diode LED may be an inorganic light-emitting diode including an inorganic material. The inorganic light-emitting diode may include a PN junction diode including inorganic semiconductor-based materials. When a voltage is applied in a forward direction to the PN junction diode, holes and electrons may be injected, and the energy generated by the recombination of the holes and electrons may be converted into light energy, which may emit light of a desired color (e.g., a certain or predetermined color). In an embodiment, the display element layer DPEL may include a quantum dot light-emitting diode. For example, the display element layer DPEL may be an emission layer, and may include an organic material, an inorganic material, quantum dots, an organic material with quantum dots, or an inorganic material with quantum dots.

The thin-film encapsulation layer TFEL may be disposed on the display element layer DPEL, and may protect the display element layer DPEL from external factors, such as moisture or foreign substances. The thin-film encapsulation layer TFEL may cover the display element layer DPEL entirely. The thin-film encapsulation layer TFEL may include at least one of an inorganic encapsulation layer including an inorganic insulating material and/or an organic encapsulation layer including an organic insulating material.

The touch sensing layer TSL may obtain coordinate information based on an external input, such as a touch event. The touch sensing layer TSL may include a touch electrode (e.g., a sensing electrode or a touch electrode), and trace lines connected to the touch electrode. The touch sensing layer TSL may be disposed on the thin-film encapsulation layer TFEL. The touch sensing layer TSL may detect an external input by using a mutual capacitance method and/or a self-capacitance method.

The optical functional layer OFL may be disposed on the touch sensing layer TSL. The optical functional layer OFL may include a light-shielding layer for blocking a reflection of external light, which may occur in the layers disposed therebelow. The optical functional layer OFL may include a color filter, which may increase an efficiency of a display element of the display element layer DPEL, such as a light-emitting diode.

In some embodiments, a cover window may be further disposed on the optical functional layer OFL, and may cover the display panel 11. The cover window may be coupled to the display panel 11 through an optical clear adhesive (OCA).

The cover window may include a glass material or a plastic material. The glass material may include an Ultra Thin Glass®. The plastic material may include polyethersulfone, polyacrylate, polyetherimide, polyethylene naphthalate, polyethylene terephthalate, polyphenylene sulfide, polyarylate, polyimide, polycarbonate, cellulose acetate propionate, or the like.

In an embodiment, an adhesive layer may be disposed between two layers selected from among the various layers described above.

In order to improve a transmittance of the opening area OA, the display panel 11 may include a transmissive opening 11OP, which penetrates through some of the layers included in the display panel 11. The transmissive opening 11OP may include openings respectively penetrating through the display element layer DPEL, the thin-film encapsulation layer TFEL, the touch sensing layer TSL, and the optical functional layer OFL. The openings defined in the display element layer DPEL, the thin-film encapsulation layer TFEL, the touch sensing layer TSL, and the optical functional layer OFL may overlap with each other, and constitute the transmissive opening 11OP defined in the display panel 11.

Referring to FIG. 1 together with FIG. 8, other elements (hereinafter, components) of the electronic device 10 may overlap with the opening area OA of the display panel 11. The component may overlap with the transmissive opening 11OP defined in the display panel 11. The component may be disposed under the display panel 11, for example, such as under a rear surface of the display panel 11. The opening area OA may be a kind of component area (e.g., a sensor area, a camera area, a speaker area, or the like), in which components for adding various functions to the electronic device 10 are located. In an embodiment, the components may include the input module 15, the non-video output module 16, and/or the communication module 17.

The component may include an electronic element. For example, the component may be an electronic element that uses light or sound. For example, the electronic element may include sensors that use light, such as infrared sensors, cameras that capture images by receiving light, sensors that output and detect light or sound to measure distances or recognize fingerprints, small lamps that output light, or speakers that output sound. The electronic element that uses light may use light in various suitable wavelength bands, such as visible light, infrared light, or ultraviolet light. The opening area OA may correspond to an area capable of transmitting light and/or sound output from the component to the outside, or traveling from the outside toward the component (e.g., the electronic element).

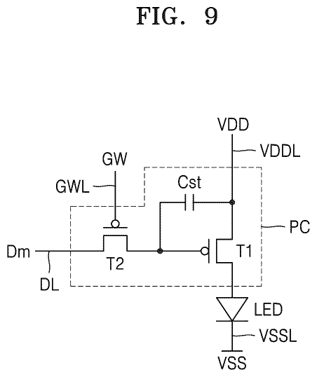

FIGS. 9 through 11 are each an equivalent circuit diagram of a pixel of a display panel according to an embodiment.

Referring to FIG. 9, the light-emitting diode LED corresponding to a pixel may be electrically connected to the pixel circuit PC. The pixel circuit PC may include a first transistor T1, a second transistor T2, and a storage capacitor Cst. The pixel circuit PC may be electrically connected to a trace line and a voltage line. The trace line may include a scan signal line GWL and a data line DL, and the voltage line may include a first voltage line VDDL.

The second transistor T2 is a data write transistor, and may be electrically connected to the scan signal line GWL and the data line DL. The scan signal line GWL may provide a scan signal GW to a gate electrode of the second transistor T2. The second transistor T2 may transmit a data signal Dm received via the data line DL to the first transistor T1, in response to the scan signal GW received via the scan signal line GWL.

The storage capacitor Cst may be electrically connected to the second transistor T2 and the first voltage line VDDL, and may store a voltage corresponding to a voltage difference between a voltage received from the second transistor T2 and a first power voltage VDD supplied via the first voltage line VDDL.

The first transistor T1 is a driving transistor, and may control a driving current flowing through the light-emitting diode LED. The first transistor T1 may be connected to the first voltage line VDDL and the storage capacitor Cst. The first transistor T1 may control a driving current flowing from the first voltage line VDDL to the light-emitting diode LED, in response to a value of the voltage stored in the storage capacitor Cst. The light-emitting diode LED may emit light having a desired luminance (e.g., a certain or predetermined luminance) according to the driving current. A first electrode (e.g., a pixel electrode or an anode) of the light-emitting diode LED may be electrically connected to the first transistor T1, and a second electrode (e.g., an opposite electrode or a cathode) may be electrically connected to a second voltage line VSSL that supplies a second power voltage VSS.

FIG. 9 shows that the pixel circuit PC includes one switching transistor (e.g., the second transistor T2) and one capacitor (e.g., the storage capacitor Cst). However, in another embodiment, the pixel circuit PC may include two or more switching transistors and/or two or more capacitors.

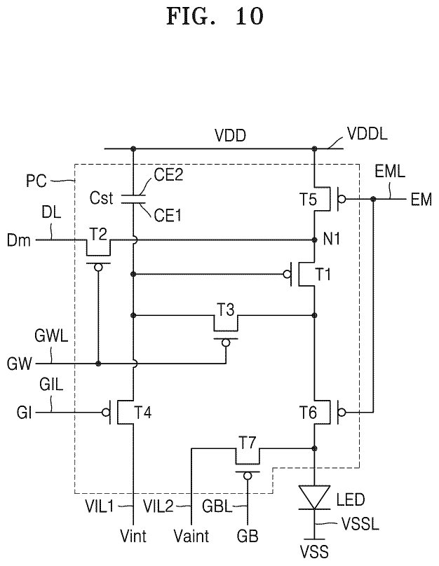

Referring to FIG. 10, the pixel circuit PC may include the first transistor T1, the second transistor T2, a third transistor T3, a fourth transistor T4, a fifth transistor T5, a sixth transistor T6, a seventh transistor T7, and the storage capacitor Cst. The first transistor T1 may be a driving transistor, and the second transistor T2, the third transistor T3, the fourth transistor T4, the fifth transistor T5, the sixth transistor T6, and the seventh transistor T7 may be switching transistors.

The pixel circuit PC may be electrically connected to trace lines and voltage lines. The trace lines may include a gate line, such as the scan signal line GWL, a bypass control line GBL, an initialization control line GIL, and an emission control line EML, and the data line DL. The voltage lines may include first and second initialization voltage lines VIL1 and VIL2, and the first voltage line VDDL.

The first voltage line VDDL may transmit the first power voltage VDD to the first transistor T1. The first initialization voltage line VIL1 may transmit a first initialization voltage Vint to the pixel circuit PC for initializing the first transistor T1. The second initialization voltage line VIL2 may transmit, to the pixel circuit PC, a second initialization voltage Vaint for initializing the first electrode (e.g., the pixel electrode or the anode) of the light-emitting diode LED.

The first transistor T1 may be electrically connected to the first voltage line VDDL via the fifth transistor T5, and may be electrically connected to the light-emitting diode LED via the sixth transistor T6. The first transistor T1 may serve as a driving transistor, and may receive the data signal Dm according to a switching operation of the second transistor T2 to supply a driving current to the light-emitting diode LED.

The second transistor T2 is a data write transistor, and may be electrically connected to the scan signal line GWL and the data line DL. The second transistor T2 may be electrically connected to the first voltage line VDDL via the fifth transistor T5. The second transistor T2 may be turned on according to the scan signal GW received via the scan signal line GWL, and may perform a switching operation for transmitting the data signal Dm received via the data line DL to a first node N1.

The third transistor T3 may be electrically connected to the scan signal line GWL, and may be electrically connected to the light-emitting diode LED via the sixth transistor T6. The third transistor T3 may be turned on according to the scan signal GW received via the scan signal line GWL, so that the first transistor T1 may be diode-connected.

The fourth transistor T4 is a first initialization transistor, and may be electrically connected to the initialization control line GIL and the first initialization voltage line VIL1. The fourth transistor T4 may be turned on according to an initialization control signal GI received via the initialization control line GIL, and may transfer the first initialization voltage Vint from the first initialization voltage line VIL1 to the gate of the first transistor T1, thereby initializing a voltage at the gate of the first transistor T1. The initialization control signal GI may correspond to a scan signal of another pixel circuit disposed in a previous row of the corresponding pixel circuit PC.

The fifth transistor T5 may be an operation control transistor, and the sixth transistor T6 may be an emission control transistor. The fifth transistor T5 and the sixth transistor T6 may be electrically connected to the emission control line EML, and may be concurrently (e.g., simultaneously or substantially simultaneously) turned on with each other according to an emission control signal EM received via the emission control line EML to form a current path, so that a driving current may flow from the first voltage line VDDL toward the light-emitting diode LED. The first electrode of the light-emitting diode LED may be electrically connected to the first transistor T1 via the sixth transistor T6, and the second electrode may be electrically connected to the second voltage line VSSL that supplies the second power voltage VSS.

The seventh transistor T7 is a second initialization transistor, and may be electrically connected to the bypass control line GBL, the second initialization voltage line VIL2, and the sixth transistor T6. The seventh transistor T7 may be turned on according to a bypass control signal GB received via the bypass control line GBL, and may transfer the second initialization voltage Vaint from the second initialization voltage line VIL2 to the first electrode of the light-emitting diode LED, thereby initializing the first electrode of the light-emitting diode LED.

The storage capacitor Cst may include a first capacitor electrode CE1 and a second capacitor electrode CE2. The first capacitor electrode CE1 may be electrically connected to the gate of the first transistor T1, and the second capacitor electrode CE2 may be electrically connected to the first voltage line VDDL. The storage capacitor Cst may store and sustain a voltage corresponding to a difference between a voltage of the first voltage line VDDL and each of voltages at opposite ends of the gate of the first transistor T1, thereby sustaining a voltage applied to the gate of the first transistor T1.

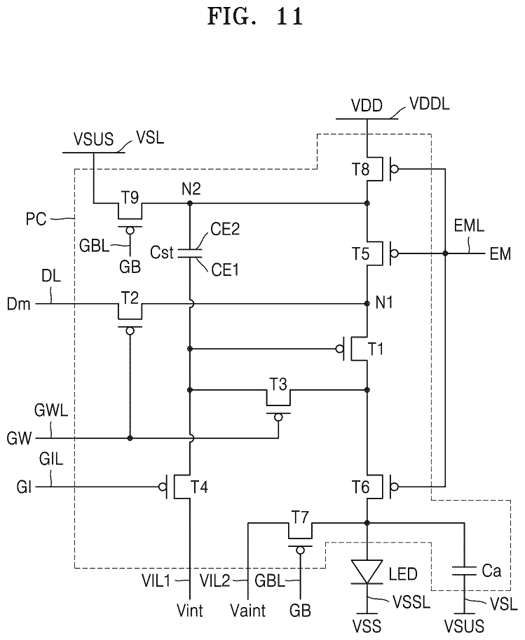

Referring to FIG. 11, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca. The first transistor T1 may be a driving transistor, and the second transistor T2, the third transistor T3, the fourth transistor T4, the fifth transistor T5, the sixth transistor T6, the seventh transistor T7, the eighth transistor T8, and the ninth transistor T9 may be switching transistors.

The pixel circuit PC may be electrically connected to trace lines and voltage lines. The trace lines may include a gate line, such as the scan signal line GWL, the bypass control line GBL, an initialization control line GIL, and the emission control line EML, and the data line DL. The voltage lines may include the first and second initialization voltage lines VIL1 and VIL2, a sustain voltage line VSL, and the first voltage line VDDL.

The first voltage line VDDL may transmit the first power voltage VDD to the first transistor T1. The first initialization voltage line VIL1 may transmit the first initialization voltage Vint to the pixel circuit PC for initializing the first transistor T1. The second initialization voltage line VIL2 may transfer, to the pixel circuit PC, the second initialization voltage Vaint for initializing the first electrode of the light-emitting diode LED. In an initialization period and a data write period, the sustain voltage line VSL may provide a sustain voltage VSUS to a second node N2, for example, such as to the second capacitor electrode CE2 of the storage capacitor Cst.

The first transistor T1 may be electrically connected to the first voltage line VDDL via the fifth transistor T5 and the eighth transistor T8, and may be electrically connected to the light-emitting diode LED via the sixth transistor T6. The first transistor T1 may serve as a driving transistor, and may receive the data signal Dm according to a switching operation of the second transistor T2 to supply a driving current to the light-emitting diode LED.

The second transistor T2 may be electrically connected to the scan signal line GWL and the data line DL, and may be electrically connected to the first voltage line VDDL via the fifth transistor T5 and the eighth transistor T8. The second transistor T2 may be turned on according to the scan signal GW received via the scan signal line GWL, and may perform a switching operation for transmitting the data signal Dm received via the data line DL to the first node N1.

The third transistor T3 may be electrically connected to the scan signal line GWL, and may be electrically connected to the light-emitting diode LED via the sixth transistor T6. The third transistor T3 may be turned on according to the scan signal GW received via the scan signal line GWL, so that the first transistor T1 is diode-connected, thereby compensating for a threshold voltage of the first transistor T1.

The fourth transistor T4 may be electrically connected to the initialization control line GIL and the first initialization voltage line VIL1, and may be turned on according to the initialization control signal GI received via the initialization control line GIL so that the first initialization voltage Vint may be transferred from the first initialization voltage line VIL1 to the gate of the first transistor T1, thereby initializing the voltage at the gate of the first transistor T1. The initialization control signal GI may correspond to a scan signal of another pixel circuit disposed in a previous row of the corresponding pixel circuit PC.

The fifth transistor T5, the sixth transistor T6, and the eighth transistor T8 may be electrically connected to the emission control line EML, and may be concurrently (e.g., simultaneously or substantially simultaneously) turned on with each other according to an emission control signal EM received via the emission control line EML to form a current path, so that a driving current may flow from the first voltage line VDDL toward the light-emitting diode LED. The first electrode of the light-emitting diode LED may be electrically connected to the first transistor T1 via the sixth transistor T6, and the second electrode may be electrically connected to the second voltage line VSSL that supplies the second power voltage VSS.

The seventh transistor T7 is a second initialization transistor, and may be electrically connected to the bypass control line GBL, the second initialization voltage line VIL2, and the sixth transistor T6. The seventh transistor T7 may be turned on according to a bypass control signal GB received via the bypass control line GBL, so that the second initialization voltage Vaint is transferred from the second initialization voltage line VIL2 to the first electrode of the light-emitting diode LED, thereby initializing the first electrode of the light-emitting diode LED.

The ninth transistor T9 may be electrically connected to the bypass control line GBL, the second capacitor electrode CE2 of the storage capacitor Cst, and the sustain voltage line VSL. The ninth transistor T9 may be turned on according to a bypass control signal GB received via the bypass control line GBL, and may transfer the sustain voltage VSUS to the second node N2, for example, such as to the second capacitor electrode CE2 of the storage capacitor Cst, in the initialization period and the data write period.

Each of the eighth transistor T8 and the ninth transistor T9 may be electrically connected to the second node N2, for example, such as to the second capacitor electrode CE2 of the storage capacitor Cst. In an embodiment, the eighth transistor T8 may be turned off and the ninth transistor T9 may be turned on in the initialization period and the data write period, and the eighth transistor T8 may be turned on and the ninth transistor T9 may be turned off in an emission period.

The storage capacitor Cst may include the first capacitor electrode CE1 and the second capacitor electrode CE2. The first capacitor electrode CE1 may be electrically connected to the gate of the first transistor T1, and the second capacitor electrode CE2 may be electrically connected to the eighth transistor T8 and the ninth transistor T9.

The auxiliary capacitor Ca may be electrically connected to the sixth transistor T6, the sustain voltage line VSL, and the first electrode of the light-emitting diode LED. While the seventh transistor T7 and the ninth transistor T9 are turned on, the auxiliary capacitor Ca may store and sustain a voltage corresponding to a voltage difference between the first electrode of the light-emitting diode LED and the sustain voltage line VSL, thereby preventing or substantially preventing a black luminance from increasing when the sixth transistor T6 is turned off.

FIGS. 9 through 11 show embodiments in which the transistors of the pixel circuit PC are implemented as p-channel metal-oxide-semiconductor field-effect transistors (p-channel MOSFETs or PMOS transistors). However, the present disclosure is not limited thereto. In an embodiment, at least one of the transistors of the pixel circuit PC in FIG. 9, for example, such as the first and second transistors T1 and T2, may be implemented as an n-channel MOSFET (an NMOS transistor). In an embodiment, at least one of the transistors of the pixel circuit PC in FIG. 10, for example, such as the first to seventh transistors T1, T2, T3, T4, T5, T6, and T7, may be implemented as an NMOS transistor. For example, the first, second, fifth, sixth, and seventh transistors T1, T2, T5, T6, and T7 of the pixel circuit PC in FIG. 10 may be implemented as PMOS transistors, and the third and fourth transistors T3 and T4 may be implemented as NMOS transistors. In an embodiment, at least one of the transistors of the pixel circuit PC in FIG. 11, for example, such as the first to ninth transistors T1, T2, T3, T4, T5, T6, T7, T8, and T9, may be implemented as an NMOS transistor. For example, the first, second, fifth, sixth, seventh, eighth, and ninth transistors T1, T2, T5, T6, T7, T8, and T9 of the pixel circuit PC in FIG. 11 may be implemented as PMOS transistors, and the third and fourth transistors T3 and T4 may be implemented as NMOS transistors.

FIG. 12 is a cross-sectional view of a display area of a display panel according to an embodiment.

Referring to FIG. 12, the display element layer DPEL, the thin-film encapsulation layer TFEL, the touch sensing layer TSL, and the optical functional layer OFL may be sequentially disposed over the substrate 100.

The display element layer DPEL may include the light-emitting diode LED, and a thin-film transistor TFT connected to the light-emitting diode LED. For convenience of illustration, FIG. 12 may schematically illustrate a portion of any one of the pixel circuits PC described above with reference to FIGS. 9 to 11. In an embodiment, the thin-film transistor TFT connected to the light-emitting diode LED may correspond to a transistor connected to the light-emitting diode LED from among the transistors shown in FIGS. 9 to 11, for example, such as the first transistor T1 or the sixth transistor T6.

The substrate 100 may include a glass material or a polymer resin. In an embodiment, the substrate 100 may include a laminated structure of a base layer including a polymer resin, and a barrier layer including an inorganic insulating material. The polymer resin may include at least one of various suitable materials, such as polyethersulfone, polyarylate, polyetherimide, polyethylene naphthalate, polyethylene terephthalate, polyphenylene sulfide, polyimide, polycarbonate, cellulose triacetate, and/or cellulose acetate propionate. The inorganic insulating material may include silicon oxide (SiO₂) and/or silicon nitride (SiNₓ).

A first conductive layer 101 may be disposed on the substrate 100. In an embodiment, the first conductive layer 101 may include power lines and/or trace lines. In an embodiment, the first conductive layer 101 may be disposed under a semiconductor layer 103, for example, such as an active pattern ACT, to block radio waves and/or light originating from a lower portion of the display panel 11 from being transferred to the active pattern ACT. In an embodiment, the first conductive layer 101 may include a metal (e.g., having light-shielding properties). In an embodiment, the first conductive layer 101 may include at least one of various suitable materials, such as aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may have a single-layer structure or a multi-layered structure.

A first insulating layer 102 may be disposed on the first conductive layer 101. The first insulating layer 102 may cover the first conductive layer 101 entirely. The first insulating layer 102 may have a flat or substantially flat upper surface. The first insulating layer 102 may include an inorganic insulating material. In an embodiment, the first insulating layer 102 may include at least one of various suitable materials, such as SiO₂, SiNₓ, silicon oxynitride (SiON), aluminum oxide (Al₂O₃), titanium oxide (TiO₂), tantalum oxide (Ta₂O₅), hafnium oxide (HfO₂), and/or zinc peroxide (ZnO₂), and may have a single-layer structure or a multi-layered structure. In an embodiment, the first insulating layer 102 may be a buffer layer.

The thin-film transistor TFT and an inorganic insulating layer IIL may be disposed on the first insulating layer 102. The inorganic insulating layer IIL may include a plurality of layers, and each of elements of the thin-film transistor TFT may be disposed between corresponding layers of the inorganic insulating layer IIL. The thin-film transistor TFT may include the active pattern ACT and a gate electrode GE. The inorganic insulating layer IIL may include a second insulating layer 104, a third insulating layer 106, and a fourth insulating layer 108.

The semiconductor layer 103 may be disposed on the first insulating layer 102. The semiconductor layer 103 may include the active pattern ACT. The active pattern ACT may include a source region overlapping with a source electrode SE, a drain region overlapping with a drain electrode DE, and a channel region between the source region and the drain region. The channel region may overlap with the gate electrode GE. The source region and the drain region may be doped with impurities (e.g., dopants).

The second insulating layer 104 may be disposed on the semiconductor layer 103. The second insulating layer 104 may cover the semiconductor layer 103, for example, such as the active pattern ACT. The second insulating layer 104 may include an inorganic insulating material. In an embodiment, the second insulating layer 104 may include at least one of various suitable materials, such as SiO₂, SiNₓ, SiON, Al₂O₃, TiO₂, Ta₂O₅, HfO₂, and/or ZnO₂, and may have a single-layer structure or a multi-layered structure. In an embodiment, the second insulating layer 104 may be a first gate insulating layer.

The storage capacitor Cst may be disposed on the second insulating layer 104. The storage capacitor Cst may include the first capacitor electrode CE1 and the second capacitor electrode CE2. The first capacitor electrode CE1 and the second capacitor electrode CE2 may overlap with each other, and the second capacitor electrode CE2 may be disposed on the first capacitor electrode CE1.

A second conductive layer 105 may be disposed on the second insulating layer 104. The second conductive layer 105 may include the gate electrode GE of the thin-film transistor TFT and the first capacitor electrode CE1 of the storage capacitor Cst. In an embodiment, the gate electrode GE and the first capacitor electrode CE1 may be integrally provided with each other as a single body, as shown in FIG. 12. In an embodiment, the gate electrode GE and the first capacitor electrode CE1 may be provided separately from each other. In an embodiment, the second conductive layer 105 may include at least one of various suitable materials, such as Al, Pt, Pd, Ag, Mg, Au, Ni, Nd, Ir, Cr, Ca, Mo, Ti, W, and/or Cu, and may have a single-layer structure or a multi-layered structure.

The third insulating layer 106 may be disposed on the second conductive layer 105. The third insulating layer 106 may cover the second conductive layer 105, for example, such as the gate electrode GE and the first capacitor electrode CE1. The third insulating layer 106 may include an inorganic insulating material. In an embodiment, the third insulating layer 106 may include at least one of various suitable materials, such as SiO₂, SiNₓ, SiON, Al₂O₃, TiO₂, Ta₂O₅, HfO₂, and/or ZnO₂, and may have a single-layer structure or a multi-layered structure. In an embodiment, the third insulating layer 106 may be a second gate insulating layer.

A third conductive layer 107 may be disposed on the third insulating layer 106. The third conductive layer 107 may include the second capacitor electrode CE2. The second capacitor electrode CE2 may overlap with the first capacitor electrode CE1. In an embodiment, the third conductive layer 107 may include at least one of various suitable materials, such as Al, Pt, Pd, Ag, Mg, Au, Ni, Nd, Ir, Cr, Ca, Mo, Ti, W, and/or Cu, and may have a single-layer structure or a multi-layered structure.

The fourth insulating layer 108 may be disposed on the third conductive layer 107. The fourth insulating layer 108 may cover the third conductive layer 107, for example, such as the second capacitor electrode CE2. The fourth insulating layer 108 may include an inorganic insulating material. In an embodiment, the fourth insulating layer 108 may include at least one of various suitable materials, such as SiO₂, SiNₓ, SiON, Al₂O₃, TiO₂, Ta₂O₅, HfO₂, and/or ZnO₂, and may have a single-layer structure or a multi-layered structure. In an embodiment, the fourth insulating layer 108 may be an interlayer insulating layer.

A fourth conductive layer 109 may be disposed on the fourth insulating layer 108. The fourth conductive layer 109 may include the source electrode SE and the drain electrode DE. The source electrode SE may overlap with the source region of the active pattern ACT. The source electrode SE may be connected to the active pattern ACT (e.g., the source region) through an opening defined in (e.g., penetrating) the inorganic insulating layer IIL (e.g., the second to fourth insulating layers 104, 106, and 108). The drain electrode DE may overlap with the drain region of the active pattern ACT. The drain electrode DE may be connected to the active pattern ACT (e.g., the drain region) through an opening defined in (e.g., penetrating) the inorganic insulating layer IIL (e.g., the second to fourth insulating layers 104, 106, and 108). In an embodiment, the fourth conductive layer 109 may include at least one of various suitable materials, such as Al, Pt, Pd, Ag, Mg, Au, Ni, Nd, Ir, Cr, Ca, Mo, Ti, W, and/or Cu, and may have a single-layer structure or a multi-layered structure.

FIG. 12 shows an embodiment in which the second to fourth insulating layers 104, 106, and 108 each have a flat or substantially flat upper surface. However, the present disclosure is not limited thereto, and the second to fourth insulating layers 104, 106, and 108 may each have an upper surface shape (e.g., an unevenness) corresponding to a shape of the layer disposed therebelow.

A fifth insulating layer 110 may be disposed on the fourth conductive layer 109. The fifth insulating layer 110 may cover the fourth conductive layer 109, for example, such as the source electrode SE and the drain electrode DE. The fifth insulating layer 110 may have a flat or substantially flat upper surface. The fifth insulating layer 110 may include an organic insulating material. In an embodiment, the fifth insulating layer 110 may include at least one of various suitable materials, such as general-purpose polymers, such as benzocyclobutene, polyimide, hexamethyldisiloxane, polymethylmethacrylate, or polystyrene, polymer derivatives having a phenol-based group, acryl-based polymers, imide-based polymers, aryl ether-based polymers, amide-based polymers, fluorine-based polymers, p-xylene-based polymers, or vinyl alcohol-based polymers, and the fifth insulating layer 110 may have a single-layer structure or a multi-layered structure. In an embodiment, the fifth insulating layer 110 may be a first via layer.

A fifth conductive layer 111 may be disposed on the fifth insulating layer 110. The fifth conductive layer 111 may include a contact metal connecting the fourth conductive layer 109 (e.g., the drain electrode DE) to a first electrode 113 of the light-emitting diode LED. The fifth conductive layer 111 may further include gate electrodes, trace lines, power lines, or the like of other transistors. In an embodiment, the fifth conductive layer 111 may include at least one of various suitable materials, such as Al, Pt, Pd, Ag, Mg, Au, Ni, Nd, Ir, Cr, Ca, Mo, Ti, W, and/or Cu, and may have a single-layer structure or a multi-layered structure.

A sixth insulating layer 112 may be disposed on the fifth conductive layer 111. The sixth insulating layer 112 may cover the fifth conductive layer 111. The sixth insulating layer 112 may have a flat or substantially flat upper surface. The sixth insulating layer 112 may include an organic insulating material. In an embodiment, the sixth insulating layer 112 may include at least one of various suitable materials, such as general-purpose polymers, such as benzocyclobutene, polyimide, hexamethyldisiloxane, polymethylmethacrylate, or polystyrene, polymer derivatives having a phenol-based group, acryl-based polymers, imide-based polymers, aryl ether-based polymers, amide-based polymers, fluorine-based polymers, p-xylene-based polymers, or vinyl alcohol-based polymers, and the sixth insulating layer 112 may have a single-layer structure or a multi-layered structure. In an embodiment, the sixth insulating layer 112 may be a second via layer.

The light-emitting diode LED may be disposed on the sixth insulating layer 112. The light-emitting diode LED may include the first electrode 113 and a second electrode 119, which are opposite to each other, and an intermediate layer 115 between the first electrode 113 and the second electrode 119. In an embodiment, the first electrode 113 of the light-emitting diode LED may correspond to an anode, and the second electrode 119 may correspond to a cathode.

The first electrode 113 of the light-emitting diode LED may be disposed on the sixth insulating layer 112. The first electrode 113 may be connected to the fifth conductive layer 111 through an opening defined in (e.g., penetrating) the sixth insulating layer 112. The first electrode 113 may be connected to the thin-film transistor TFT (e.g., electrically connected thereto) through the fifth conductive layer 111 and the drain electrode DE. The first electrode 113 may include a conductive oxide, such as indium tin oxide (ITO), indium zinc oxide (IZO), zinc oxide (ZnO), indium oxide (In2O3), indium gallium oxide (IGO), or aluminum zinc oxide (AZO). The first electrode 113 may include a reflective film including Ag, Mg, Al, Pt, Pd, Au, Ni, Nd, Ir, Cr, or a suitable compound thereof. However, the elements and the materials of the first electrode 113 are not limited to those described above, and may be variously modified as needed or desired.

A pixel-defining layer 114 may be disposed on the sixth insulating layer 112. The pixel-defining layer 114 may cover an edge of the first electrode 113. In other words, the pixel-defining layer 114 may be opened to expose a portion of a central portion of the first electrode 113. A size and a shape of an emission area of the light-emitting diode LED may be determined by (e.g., may be defined by) the opening defined in (e.g., penetrating) the pixel-defining layer 114. In an embodiment, the pixel-defining layer 114 may include an organic insulating material. In an embodiment, the pixel-defining layer 114 may include at least one of various suitable materials, such as general-purpose polymers, such as benzocyclobutene, polyimide, hexamethyldisiloxane, polymethylmethacrylate, or polystyrene, polymer derivatives having a phenol-based group, acryl-based polymers, imide-based polymers, aryl ether-based polymers, amide-based polymers, fluorine-based polymers, p-xylene-based polymers, or vinyl alcohol-based polymers, and the pixel-defining layer 114 may have a single-layer structure or a multi-layered structure.

The intermediate layer 115 may be disposed on the first electrode 113. The intermediate layer 115 may include first and second common layers 116 and 118 disposed on the pixel-defining layer 114, and an emission layer 117 disposed in the opening defined in (e.g., penetrating) the pixel-defining layer 114. The first common layer 116 may be disposed on the second common layer 118. In an embodiment, the first common layer 116 may be disposed on the pixel-defining layer 114, the emission layer 117 may be disposed on the first common layer 116 in the opening defined in (e.g., penetrating) the pixel-defining layer 114, and the second common layer 118 may be disposed on the first common layer 116 to cover the emission layer 117. In other words, the emission layer 117 may be disposed in the opening defined in (e.g., penetrating) the pixel-defining layer 114, and may be disposed between the first common layer 116 and the second common layer 118.

The emission layer 117 may include a low-molecular weight material or a polymer material, which emits light of a desired color (e.g., a certain or predetermined color) when a current flows. The first common layer 116 may include an electron transport layer (ETL) and/or an electron injection layer (EIL). The second common layer 118 may include a hole transport layer (HTL) and/or a hole injection layer (HIL). In some embodiments, the first common layer 116 or the second common layer 118 may be omitted as needed or desired. In some embodiments, the first common layer 116 and the second common layer 118 may change positions with each other.

The second electrode 119 may be disposed on the intermediate layer 115. For example, the second electrode 119 may be disposed on the second common layer 118. The second electrode 119 may be disposed to cover the intermediate layer 115 entirely. The second electrode 119 may include a conductive material. For example, the second electrode 119 may include a transparent layer (or a translucent layer) including Ag, Mg, Al, Pt, Pd, Au, Ni, Nd, Ir, Cr, Li, Ca, or a suitable alloy thereof. As another example, the second electrode 119 may further include a layer including an oxide, such as ITO, IZO, ZNO, or In₂O₃, on the transparent layer (or the translucent layer) including one or more of the materials described above.

The thin-film encapsulation layer TFEL may be disposed on the second electrode 119, and may cover the light-emitting diode LED entirely. The thin-film encapsulation layer TFEL may include at least one inorganic layer and at least one organic layer. In an embodiment, the thin-film encapsulation layer TFEL may include a first inorganic encapsulation layer 120, a second inorganic encapsulation layer 122, and an organic encapsulation layer 121 between the first inorganic encapsulation layer 120 and the second inorganic encapsulation layer 122. In an embodiment, the first inorganic encapsulation layer 120 and the second inorganic encapsulation layer 122 may each have an upper surface shape (e.g., an unevenness) according to a shape of the layer disposed therebelow. In an embodiment, the organic encapsulation layer 121 may have a flat or substantially flat upper surface.

The first inorganic encapsulation layer 120 and/or the second inorganic encapsulation layer 122 may include at least one of various suitable materials, such as SiO₂, SiNₓ, SiON, Al₂O₃, TiO₂, Ta₂O₅, HfO₂, and/or ZnO₂, and may have a single-layer structure or a multi-layered structure. The organic encapsulation layer 121 may include a polymer-based material. Examples of the polymer-based material may include a silicon-based resin, an acryl-based resin, an epoxy-based resin, polyimide, and polyethylene.

The touch sensing layer TSL may be disposed on the thin-film encapsulation layer TFEL. The touch sensing layer TSL may include a touch electrode layer for detecting an external input, for example, such as a touch event, and a touch insulating layer between electrode layers. The touch sensing layer TSL may include a first touch insulating layer 123, a first touch electrode layer 124, a second touch insulating layer 125, a second touch electrode layer 126, and a third touch insulating layer 127.

The first touch insulating layer 123 may be disposed on the thin-film encapsulation layer TFEL, for example, such as on the second inorganic encapsulation layer 122 of the thin-film encapsulation layer TFEL. The first touch electrode layer 124 may be disposed on the first touch insulating layer 123. The second touch insulating layer 125 may be disposed on the first touch electrode layer 124, and may cover the first touch electrode layer 124. The second touch electrode layer 126 may be disposed on the second touch insulating layer 125. The third touch insulating layer 127 may be disposed on the second touch electrode layer 126, and may cover the second touch electrode layer 126. The second touch electrode layer 126 may be connected to the first touch electrode layer 124 through an opening defined in (e.g., penetrating) the second touch insulating layer 125. In an embodiment, the second touch electrode layer 126 may include a sensing electrode, and the first touch electrode layer 124 may include a bridge electrode.

In an embodiment, the first touch insulating layer 123 may include an inorganic insulating material. In an embodiment, the first touch insulating layer 123 may include at least one of various suitable materials, such as SiO₂, SiNₓ, SiON, Al₂O₃, TiO₂, Ta₂O₅, HfO₂, and/or ZnO₂, and may have a single-layer structure or a multi-layered structure.

In an embodiment, the second touch insulating layer 125 and the third touch insulating layer 127 may include an organic insulating material. In an embodiment, the second touch insulating layer 125 and/or the third touch insulating layer 127 may include an acryl-based organic insulating material. In an embodiment, the second touch insulating layer 125 and/or the third touch insulating layer 127 may have a flat or substantially flat upper surface.

The first touch electrode layer 124 and the second touch electrode layer 126 may not entirely overlap with an emission area of the light-emitting diode LED. In an embodiment, the first touch electrode layer 124 and the second touch electrode layer 126 may not overlap with the emission layer 117 of the light-emitting diode LED. In other words, the first touch electrode layer 124 and the second touch electrode layer 126 may have an opening that overlaps with an emission area of the light-emitting diode LED or the emission layer 117.

The optical functional layer OFL may be disposed on the touch sensing layer TSL. The optical functional layer OFL may include a light-shielding layer 128, a color filter 129, and an overcoat layer 130. The overcoat layer 130 may cover the light-shielding layer 128 and the color filter 129, and may have a flat or substantially flat upper surface.

The light-shielding layer 128 may be disposed on the touch sensing layer TSL, for example, such as on the third touch insulating layer 127. The light-shielding layer 128 may include a light-shielding material, and may cover the first and second touch electrode layers 124 and 126 to prevent or substantially prevent the first and second touch electrode layers 124 and 126 from reflecting external light and being visible to a user. However, the light-shielding layer 128 is not limited thereto. The light-shielding layer 128 may be opened, such that light emitted from the light-emitting diode LED may pass therethrough. An opening of the light-shielding layer 128 may overlap with the light-emitting diode LED, for example, such as the emission layer 117.

The color filter 129 may be disposed on the light-shielding layer 128. The color filter 129 may overlap with the opening defined in (e.g., penetrating) the light-shielding layer 128, and a portion of the color filter 129 may be disposed in the opening defined in (e.g., penetrating) the light-shielding layer 128. The color filter 129 may transmit light of a color (e.g., a wavelength range) corresponding to light emitted from the light-emitting diode LED. For example, when the emission layer 117 of the light-emitting diode LED emits red light, the color filter 129 may transmit light in a red wavelength range.

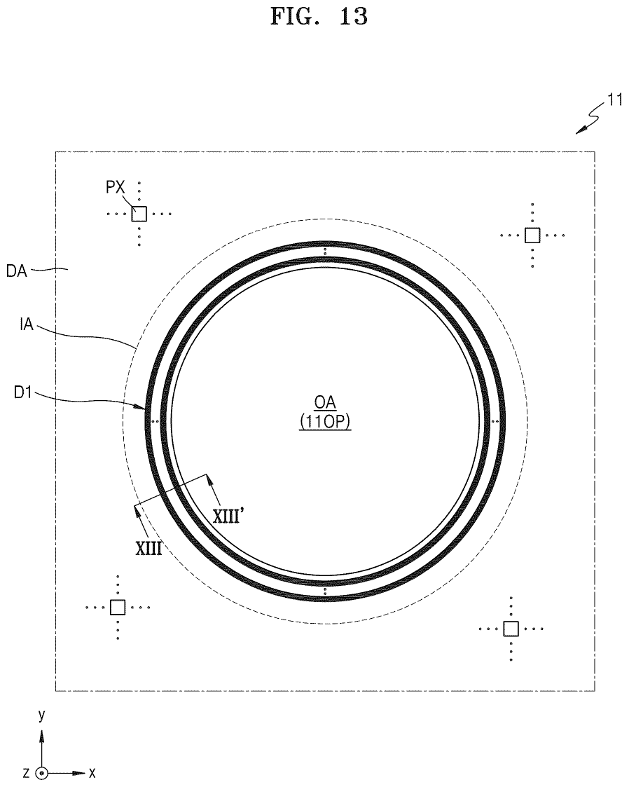

FIG. 13 is a plan view of a display panel according to an embodiment.

Referring to FIG. 13, the transmissive opening 11OP of the display panel 11 may correspond to the opening area OA. In other words, the transmissive opening 11OP overlapping with the opening area OA may be defined in the display panel 11.

The display panel 11 may include at least one first dam D1 in the intermediate area IA. In an embodiment, the first dam D1 may at least partially or entirely surround (e.g., around a periphery of) the opening area OA or the transmissive opening 11OP. In an embodiment, the first dam D1 may have a frame shape or a closed-loop shape. In an embodiment, the first dam D1 may correspond to a shape of the intermediate area IA.

In an embodiment, the display panel 11 may have a plurality of first dams D1. In an embodiment, the plurality of first dams D1 may be disposed concentrically. In an embodiment, one of the plurality of first dams D1 may at least partially or entirely surround (e.g., around a periphery of) another one of the plurality of first dams D1. In an embodiment, the plurality of first dams D1 may have a plurality of closed loops having a concentric shape.

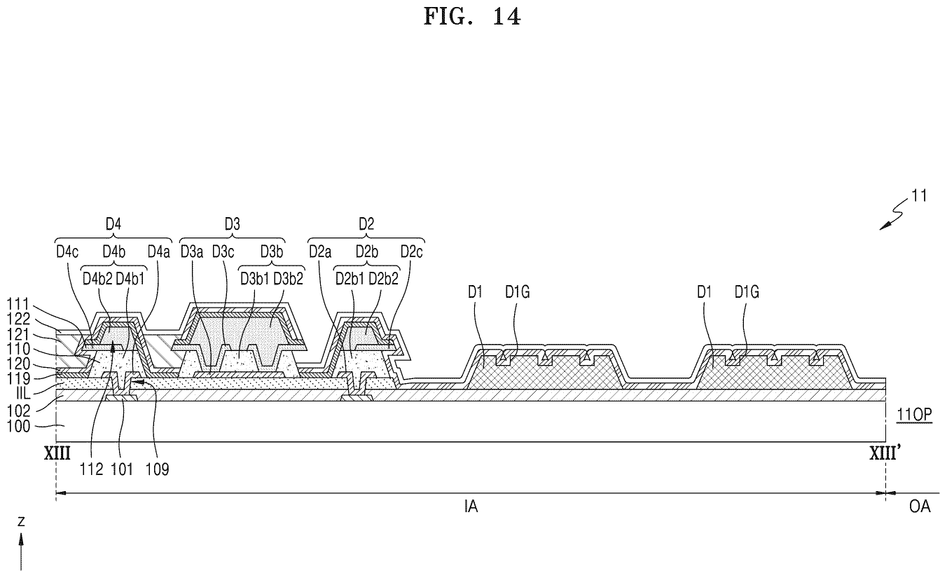

For convenience of illustration, FIG. 13 does not show a second dam D2, a third dam D3, and a fourth dam D4 (e.g., see FIG. 14) described in more detail below. However, the present disclosure is not limited thereto or thereby.

FIG. 14 is a cross-sectional view of a display panel according to an embodiment. FIG. 14 shows a cross-sectional view of a display panel, for example, taken along the line XIII-XIII′ in FIG. 13.

Referring to FIG. 14, the first insulating layer 102 may be disposed on the substrate 100. In an embodiment, the first insulating layer 102 may be omitted as needed or desired. The first dam D1, the second dam D2, the third dam D3, and the fourth dam D4 may be disposed on the first insulating layer 102. In an embodiment, the plurality of first dams D1 may be disposed on the first insulating layer 102. FIG. 14 shows two first dams D1. However, the present disclosure is not limited to a specific number of first dams D1. In an embodiment, one first dam D1 may be provided, or N first dams D1 (where N is a natural number of 3 or more) may be provided.

At least one first dam D1, the second dam D2, the third dam D3, and the fourth dam D4 may be disposed in the intermediate area IA. In an embodiment, the at least one first dam D1, the second dam D2, the third dam D3, and the fourth dam D4 may be sequentially disposed in a direction away from the opening area OA. In an embodiment, referring to FIG. 13 together with FIG. 14, the second dam D2 may be disposed between the first dam D1 and the display area DA. In other words, the first dam D1 may be disposed between the second dam D2 and the opening area OA. In an embodiment, the second dam D2 may be disposed between the first dam D1 and the third dam D3. In an embodiment, the third dam D3 may be disposed between the second dam D2 and the fourth dam D4.

At least one first groove D1G may be defined in the first dam D1. FIG. 14 shows an embodiment in which three first grooves D1G are defined in one first dam D1, but the present disclosure is not limited thereto. The number of first grooves D1G defined in one first dam D1 may be variously modified as needed or desired. In an embodiment, the first groove D1G may be defined in an upper surface, for example, such as a surface facing the z direction, of the first dam D1. In an embodiment, the first groove D1G may be defined in the form of a blind hole, for example, which does not pass through the first dam D1.

In an embodiment, the first dam D1 may include an organic insulating material.

In an embodiment, the first dam D1 may include a same material as that of the fifth insulating layer 110. In an embodiment, the first dam D1 may be formed in the same process as that of the fifth insulating layer 110. In an embodiment, the first dam D1 may be considered as a portion of the fifth insulating layer 110.

In an embodiment, the first dam D1 may include a same material as that of the sixth insulating layer 112. In an embodiment, the first dam D1 may be formed in a same process as that of the sixth insulating layer 112. In an embodiment, the first dam D1 may be considered as a portion of the sixth insulating layer 112.

In an embodiment, referring to FIG. 12 together with FIG. 14, the first dam D1 may include a same material as that of the pixel-defining layer 114. In an embodiment, the first dam D1 may be formed in a same process as that of the pixel-defining layer 114. In an embodiment, the first dam D1 may be considered as a portion of the pixel-defining layer 114.

In an embodiment, the first dam D1 may be provided as a separate organic insulating layer (e.g., a spacer layer) different from the fifth insulating layer 110, the sixth insulating layer 112, and the pixel-defining layer 114. In an embodiment, the spacer layer may include an organic insulating material. In an embodiment, the spacer layer may include at least one of various suitable materials, such as general-purpose polymers, such as benzocyclobutene, polyimide, hexamethyldisiloxane, polymethylmethacrylate, or polystyrene, polymer derivatives having a phenol-based group, acryl-based polymers, imide-based polymers, aryl ether-based polymers, amide-based polymers, fluorine-based polymers, p-xylene-based polymers, or vinyl alcohol-based polymers, and the spacer layer may have a single-layer structure or a multi-layered structure.

The second dam D2 may be disposed on the inorganic insulating layer IIL, which extends into the intermediate area IA. In an embodiment, the second dam D2 may include a first-first metal portion D2a, a first organic portion D2b, and a first-second metal portion D2c. The first organic portion D2b may include a first-first organic portion D2b1 and a first-second organic portion D2b2.

The first-first metal portion D2a may be disposed on the inorganic insulating layer IIL. In an embodiment, the first-first metal portion D2a may be connected to the first conductive layer 101 via an opening defined in (e.g., penetrating) the inorganic insulating layer IIL and the first insulating layer 102. In an embodiment, the first-first metal portion D2a may include a same material as that of the fourth conductive layer 109. In an embodiment, the first-first metal portion D2a and the fourth conductive layer 109 may be formed in a same process as each other. In an embodiment, the first-first metal portion D2a may be considered as a portion of the fourth conductive layer 109.

In an embodiment, the first-first organic portion D2b1 may be disposed on the first-first metal portion D2a. In an embodiment, the first-first organic portion D2b1 may cover the first-first metal portion D2a entirely. In an embodiment, the first-first organic portion D2b1 may include a same material as that of the fifth insulating layer 110. In an embodiment, the first-first organic portion D2b1 and the fifth insulating layer 110 may be formed in a same process as each other. In an embodiment, the first-first organic portion D2b1 may be considered as a portion of the fifth insulating layer 110.

In an embodiment, the first-second organic portion D2b2 may be disposed on the first-second metal portion D2c. In an embodiment, the first-second organic portion D2b2 may partially cover the first-second metal portion D2c. In an embodiment, the first-second organic portion D2b2 may include a same material as that of the sixth insulating layer 112. In an embodiment, the first-second organic portion D2b2 may be formed in a same process as that of the sixth insulating layer 112. In an embodiment, the first-second organic portion D2b2 may be considered as a portion of the sixth insulating layer 112.

The first-second metal portion D2c may be disposed within the first organic portion D2b. In an embodiment, the first-second metal portion D2c may be disposed between the first-first organic portion D2b1 and the first-second organic portion D2b2. In an embodiment, the first-second metal portion D2c may protrude beyond a side surface of the first organic portion D2b, for example, such as beyond a side surface of the first-first organic portion D2b1 and a side surface of the first-second organic portion D2b2. In other words, the first-second metal portion D2c and the first organic portion D2b may constitute an undercut (e.g., a tip) structure. In an embodiment, the first-second metal portion D2c may protrude in a direction toward the opening area OA from a side surface of the first organic portion D2b. In an embodiment, the first-second metal portion D2c may protrude in a direction toward the display area DA (e.g., see FIG. 13) from a side surface of the first organic portion D2b.

In an embodiment, the second electrode 119 may extend to the intermediate area. In an embodiment, the second electrode 119 may be disconnected by the undercut structure formed by the first-second metal portion D2c and the first organic portion D2b. In an embodiment, the second electrode 119 may be disconnected at an edge of the first-second metal portion D2c, which protrudes beyond a side surface of the first organic portion D2b. In an embodiment, the second electrode 119 may come into direct contact with an upper surface of a portion of the first-second metal portion D2c that protrudes beyond the side surface of the first organic portion D2b.

The third dam D3 may be disposed on the inorganic insulating layer IIL, which extends into the intermediate area IA. In an embodiment, the third dam D3 may include a second-first metal portion D3a, a second organic portion D3b, and a second-second metal portion D3c. The second organic portion D3b may include a second-first organic portion D3b1 and a second-second organic portion D3b2.

The second-first metal portion D3a may be disposed on the inorganic insulating layer IIL. In an embodiment, the second-first metal portion D3a may include a same material as that of the fourth conductive layer 109. In an embodiment, the second-first metal portion D3a and the fourth conductive layer 109 may be formed in a same process as each other. In an embodiment, the second-first metal portion D3a may be considered as a portion of the fourth conductive layer 109.

In an embodiment, the second-first organic portion D3b1 may be disposed on the second-first metal portion D3a. In an embodiment, the second-first organic portion D3b1 may cover the second-first metal portion D3a. In an embodiment, the second-first organic portion D3b1 may include a same material as that of the fifth insulating layer 110. In an embodiment, the second-first organic portion D3b1 and the fifth insulating layer 110 may be formed in a same process as each other. In an embodiment, the second-first organic portion D3b1 may be considered as a portion of the fifth insulating layer 110.

In an embodiment, the second-second organic portion D3b2 may be disposed on the second-second metal portion D3c. In an embodiment, the second-second organic portion D3b2 may partially cover the second-second metal portion D3c. In an embodiment, the second-second organic portion D3b2 may include a same material as that of the sixth insulating layer 112. In an embodiment, the second-second organic portion D3b2 may be formed in a same process as that of the sixth insulating layer 112. In an embodiment, the second-second organic portion D3b2 may be considered as a portion of the sixth insulating layer 112.

The second-second metal portion D3c may be disposed within the second organic portion D3b. In an embodiment, the second-second metal portion D3c may be disposed between the second-first organic portion D3b1 and the second-second organic portion D3b2. In an embodiment, the second-second metal portion D3c may protrude beyond a side surface of the second organic portion D3b, for example, such as beyond a side surface of the second-first organic portion D3b1 and a side surface of the second-second organic portion D3b2. In other words, the second-second metal portion D3c and the second organic portion D3b may constitute an undercut (or a tip) structure. In an embodiment, the third dam D3 may include two or more second-second metal portions D3c. In an embodiment, one of the second-second metal portions D3c may protrude in a direction toward the opening area OA from a side surface of the second organic portion D3b. In an embodiment, another one of the second-second metal portions D3c may protrude in a direction toward the display area DA (e.g., see FIG. 13) from a side surface of the second organic portion D3b. In an embodiment, the second-second metal portions D3c may be connected to the second-first metal portion D3a via an opening defined in (e.g., penetrating) the second-first organic portion D3b1.

In an embodiment, the second electrode 119 may be disconnected by the undercut structure formed by the second-second metal portion D3c and the second organic portion D3b. In an embodiment, the second electrode 119 may be disconnected at an edge of the second-second metal portion D3c that protrudes beyond a side surface of the second organic portion D3b. In an embodiment, the second electrode 119 may come into direct contact with an upper surface of a portion of the second-second metal portion D3c that protrudes beyond the side surface of the second organic portion D3b.

The fourth dam D4 may be disposed on the inorganic insulating layer IIL, which extends into the intermediate area IA. In an embodiment, the fourth dam D4 may include a third-first metal portion D4a, a third organic portion D4b, and a third-second metal portion D4c. The third organic portion D4b may include a third-first organic portion D4b1 and a third-second organic portion D4b2.

The third-first metal portion D4a may be disposed on the inorganic insulating layer IIL. In an embodiment, the third-first metal portion D4a may be connected to the first conductive layer 101 via an opening defined in (e.g., penetrating) the inorganic insulating layer IIL and the first insulating layer 102. In an embodiment, the third-first metal portion D4a may include a same material as that of the fourth conductive layer 109. In an embodiment, the third-first metal portion D4a and the fourth conductive layer 109 may be formed in a same process as each other. In an embodiment, the third-first metal portion D4a may be considered as a portion of the fourth conductive layer 109.

In an embodiment, the third-first organic portion D4b1 may be disposed on the third-first metal portion D4a. In an embodiment, the third-first organic portion D4b1 may cover the third-first metal portion D4a entirely. In an embodiment, the third-first organic portion D4b1 may include a same material as that of the fifth insulating layer 110. In an embodiment, the third-first organic portion D4b1 and the fifth insulating layer 110 may be formed in a same process as each other. In an embodiment, the third-first organic portion D4b1 may be considered as a portion of the fifth insulating layer 110.

In an embodiment, the third-second organic portion D4b2 may be disposed on the third-second metal portion D4c. In an embodiment, the third-second organic portion D4b2 may partially cover the third-second metal portion D4c. In an embodiment, the third-second organic portion D4b2 may include a same material as that of the sixth insulating layer 112. In an embodiment, the third-second organic portion D4b2 may be formed in a same process as that of the sixth insulating layer 112. In an embodiment, the third-second organic portion D4b2 may be considered as a portion of the sixth insulating layer 112.

The third-second metal portion D4c may be disposed within the third organic portion D4b. In an embodiment, the third-second metal portion D4c may be disposed between the third-first organic portion D4b1 and the third-second organic portion D4b2. In an embodiment, the third-second metal portion D4c may protrude beyond a side surface of the third organic portion D4b, for example, such as beyond a side surface of the third-first organic portion D4b1 and a side surface of the third-second organic portion D4b2. In other words, the third-second metal portion D4c and the third organic portion D4b may constitute an undercut (or a tip) structure. In an embodiment, the third-second metal portion D4c may protrude in a direction toward the display area DA (e.g., see FIG. 13) from a side surface of the third organic portion D4b. In an embodiment, the third-second metal portion D4c may protrude in a direction toward the opening area OA from a side surface of the third organic portion D4b.

In an embodiment, the second electrode 119 may be disconnected by the undercut structure formed by the third-second metal portion D4c and the third organic portion D4b. In an embodiment, the second electrode 119 may be disconnected at an edge of the third-second metal portion D4c that protrudes beyond a side surface of the third organic portion D4b. In an embodiment, the second electrode 119 may come into direct contact with an upper surface of a portion of the third-second metal portion D4c that protrudes beyond the side surface of the third organic portion D4b.

The first inorganic encapsulation layer 120 and the second inorganic encapsulation layer 122 may extend to the intermediate area IA, and may cover the first dam D1, the second dam D2, the third dam D3, and the fourth dam D4. In an embodiment, the first inorganic encapsulation layer 120 and the second inorganic encapsulation layer 122 may be disconnected by an undercut structure formed in the second-second metal portion D3c and the second organic portion D3b. In an embodiment, the first inorganic encapsulation layer 120 and the second inorganic encapsulation layer 122 may not be disconnected in the undercut structure formed in the first-second metal portion D2c and the first organic portion D2b. In other words, the first inorganic encapsulation layer 120 may integrally extend and cover an upper surface, a side surface, and a lower surface of the first-second metal portion D2c protruding beyond a side surface of the first organic portion D2b. The organic encapsulation layer 121 may be disposed between the first inorganic encapsulation layer 120 and the second inorganic encapsulation layer 122. In an embodiment, the organic encapsulation layer 121 may be disposed between the fourth dam D4 and the display area DA (e.g., see FIG. 13), and/or between the third dam D3 and the fourth dam D4. A portion of the first inorganic encapsulation layer 120 may be disposed within the first groove D1G of the first dam D1.

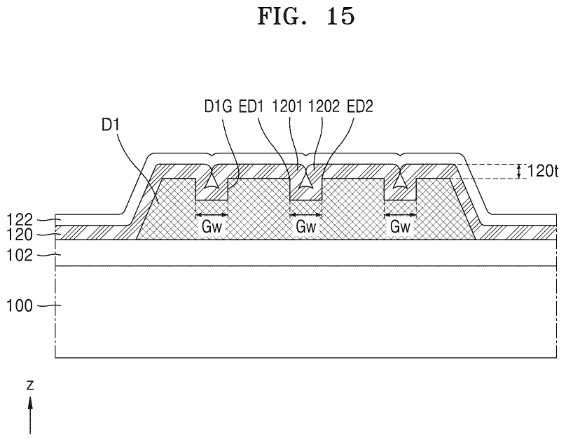

FIG. 15 is an enlarged cross-sectional view of a display panel according to an embodiment. For example, FIG. 15 is an enlarged cross-sectional view of the first dam D1.

Referring to FIG. 15, at least one first groove D1G may be defined in the first dam D1, and a portion of the first inorganic encapsulation layer 120 may be disposed within the first groove D1G of the first dam D1.

In an embodiment, the first dam D1 may include a first edge ED1 and a second edge ED2, which define the first groove D1G. The first edge ED1 and the second edge ED2 may be edges of the first dam D1, which are located at opposite sides of the first groove D1G, respectively. The first edge ED1 and the second edge ED2 may face each other. In an embodiment, a portion of the first inorganic encapsulation layer 120 disposed on the first edge ED1 and overlapping with the first edge ED1 may be defined as a first portion 1201 of the first inorganic encapsulation layer 120. In an embodiment, a portion of the first inorganic encapsulation layer 120 disposed on the second edge ED2 and overlapping with the second edge ED2 may be defined as a second portion 1202 of the first inorganic encapsulation layer 120. In an embodiment, the first portion 1201 and the second portion 1202 of the first inorganic encapsulation layer 120 may face each other. In an embodiment, the first portion 1201 and the second portion 1202 of the first inorganic encapsulation layer 120 may come into contact with each other in an area overlapping with the first groove D1G of the first dam D1. In an embodiment, when the first portion and the second portion 1202 of the first inorganic encapsulation layer 120 contact each other, the second inorganic encapsulation layer 122 may not be disposed within the first groove D1G of the first dam D1. However, the present disclosure is not limited to a case in which the second inorganic encapsulation layer 122 is not disposed within the first groove D1G of the first dam D1, and the second inorganic encapsulation layer 122 may be disposed within one first groove D1G of a plurality of first grooves D1G provided in the first dam D1, but not within another one of the first grooves D1G.

In an embodiment, a thickness of the first inorganic encapsulation layer 120 disposed on an upper surface of the first dam D1 may be defined as a first thickness 120t. In an embodiment, a width of the first groove D1G of the first dam D1, for example, such as a distance between the first edge ED1 and the second edge ED2, may be defined as a first width Gw. In an embodiment, the first width Gw may be about 1.5 to 2 times the first thickness 120t.

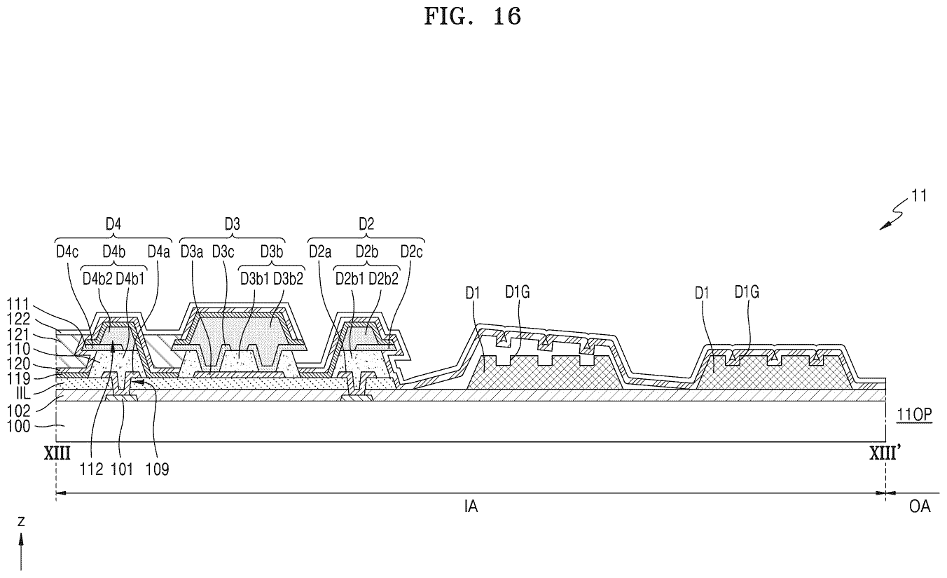

FIG. 16 is a cross-sectional view of a display panel according to an embodiment. FIG. 16 may be a cross-sectional view of the display panel, for example, taken along the line XIII-XIII′ in FIG. 13.

Referring to FIG. 16, a portion of a lower surface of the first inorganic encapsulation layer 120 disposed on the first dam D1 may be spaced apart from a portion of an upper surface of the first dam D1. When a part is spaced apart from a portion of the upper surface of the first dam D1, the plurality of first dams D1 are provided, and the part may be spaced apart from the upper surface of one first dam D1 of the plurality of first dams D1, but another part may maintain in contact with the upper surface of another one of the plurality of first dams D1, or the part may be spaced apart from a portion of the upper surface of one first dam D1, but another part may maintain in contact with another portion of the upper surface of the same first dam D1. In other words, a gap may occur between the first dam D1 and the first inorganic encapsulation layer 120. FIG. 16 shows an embodiment in which a gap occurs between the first dam D1 adjacent to the second dam D2 and the first inorganic encapsulation layer 120. However, the present disclosure is not limited thereto. In an embodiment, the gap may occur between the first dam D1 adjacent to the opening area OA and the first inorganic encapsulation layer 120. In an embodiment, the gap may occur between the first dam D1 adjacent to the second dam D2 and an inorganic encapsulation layer 120, and between the first dam D1 adjacent to the opening area OA and the inorganic encapsulation layer 120.

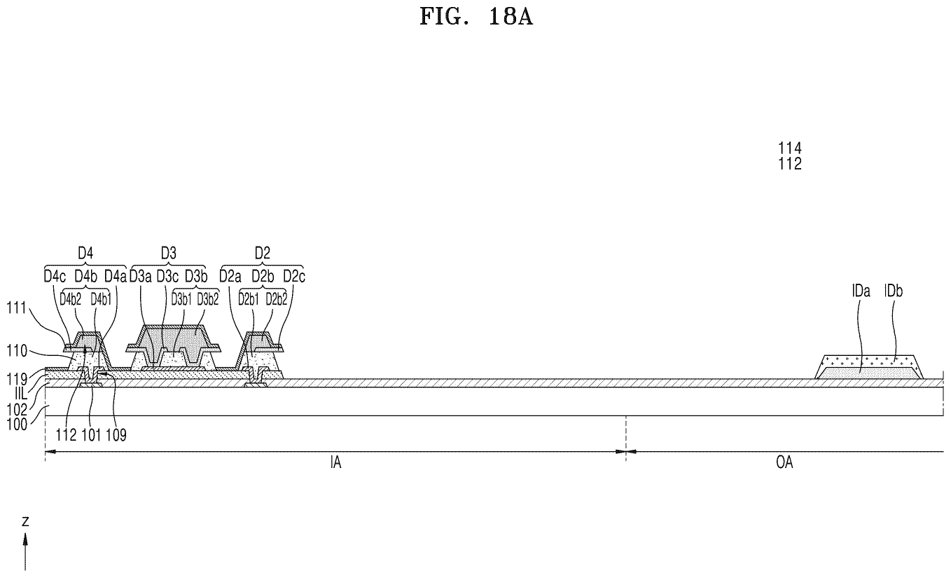

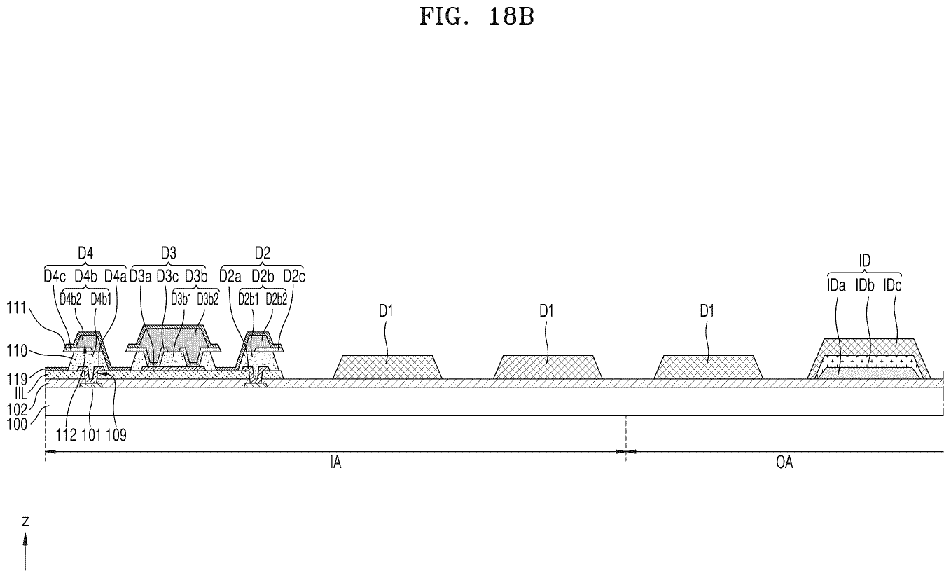

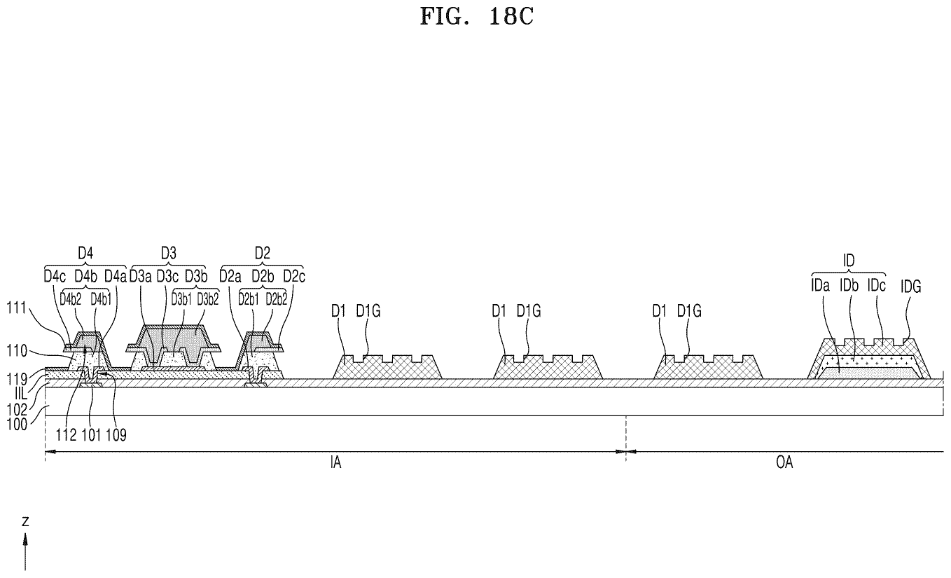

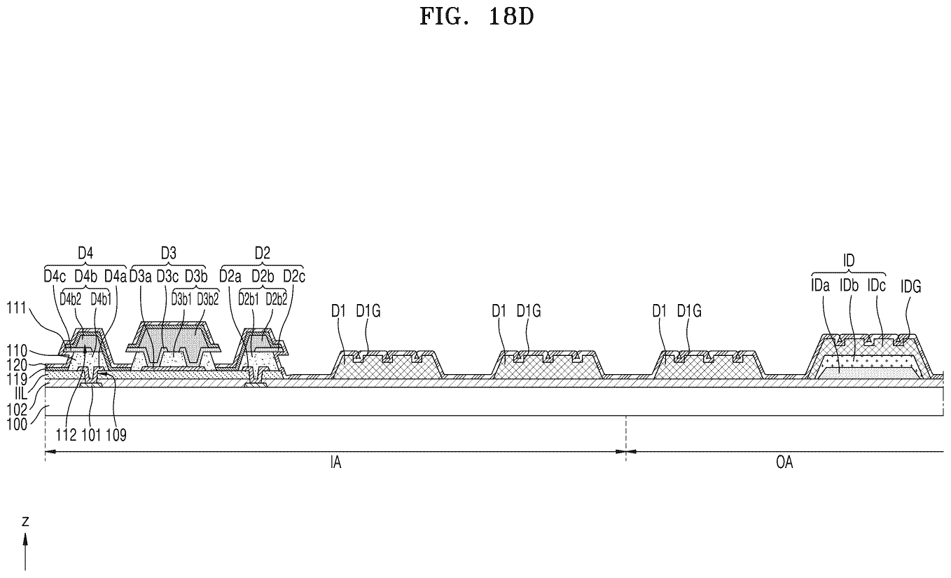

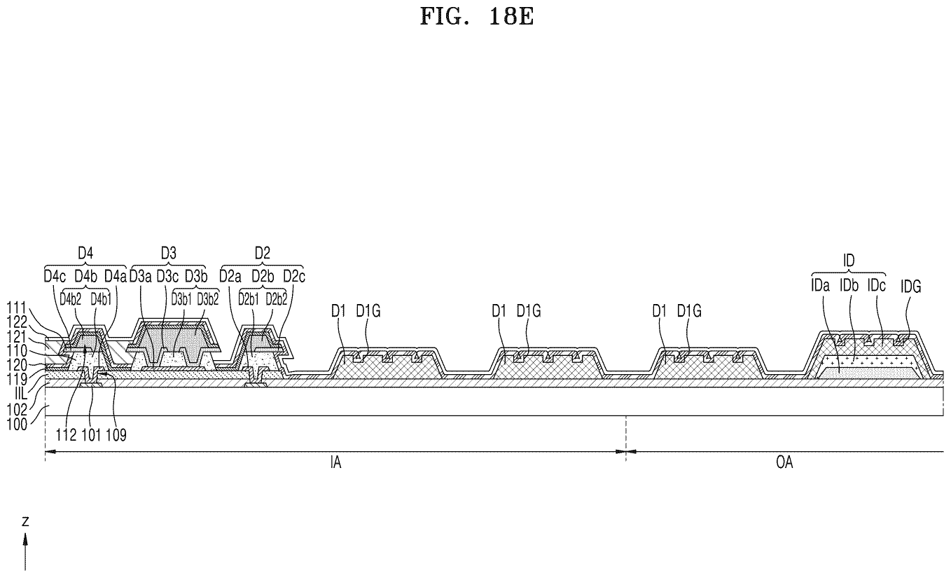

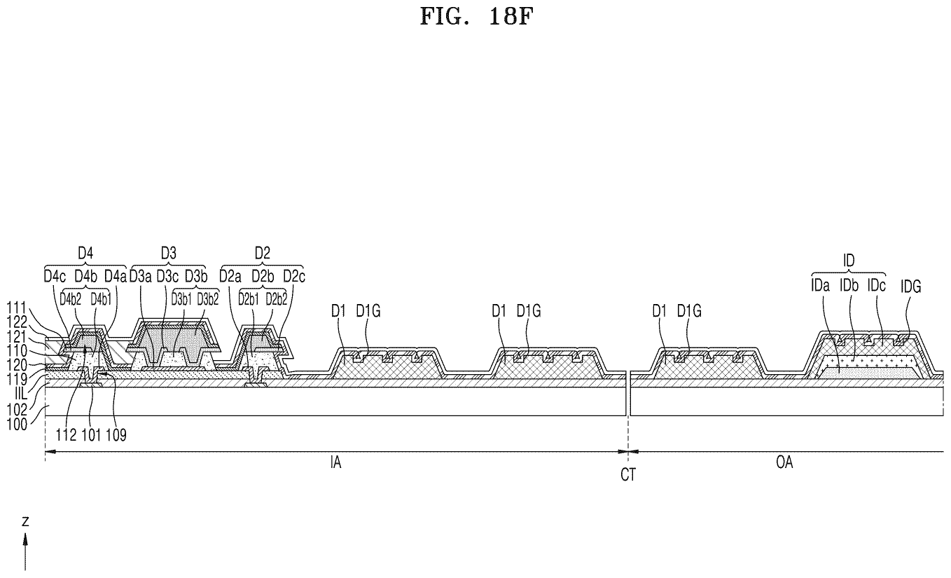

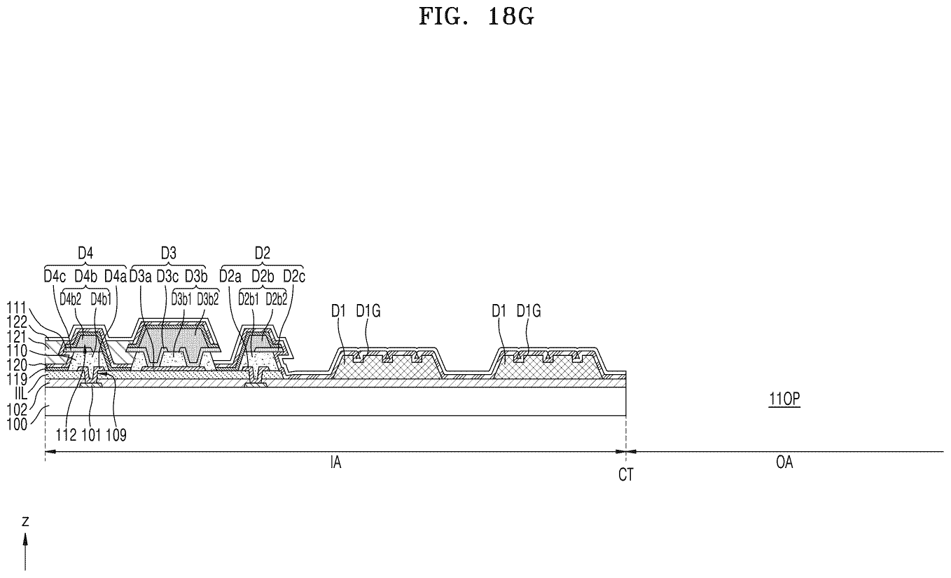

The gap may occur due to a laser cutting process and/or a transmissive opening 11OP forming process of a method of manufacturing a display panel as described below. The first dam D1 and the first groove D1G may prevent (or at least reduce) the gap from spreading to the intermediate area IA, and may prevent (or at least reduce) cracks from occurring in the first inorganic encapsulation layer 120 and/or the second inorganic encapsulation layer 122 in an area adjacent to an edge of the inorganic insulating layer IIL. In this process, a gap may partially occur between the first inorganic encapsulation layer 120 and a portion of the first dam D1, but it may be understood that the first dam D1 and the first groove D1G serve to reduce (or minimize) the gap. The embodiment shown in FIG. 14 may be understood as an embodiment in which the gap is prevented (e.g., completely prevented) by the first dam D1 and the first groove D1G, and the embodiment shown in FIG. 15 may be understood as a embodiment in which the gap is at least reduced although not completely prevented. A principle by which the first dam D1 and the first groove D1G reduce such as gap is described in more detail below with reference to FIGS. 18A to 18G.

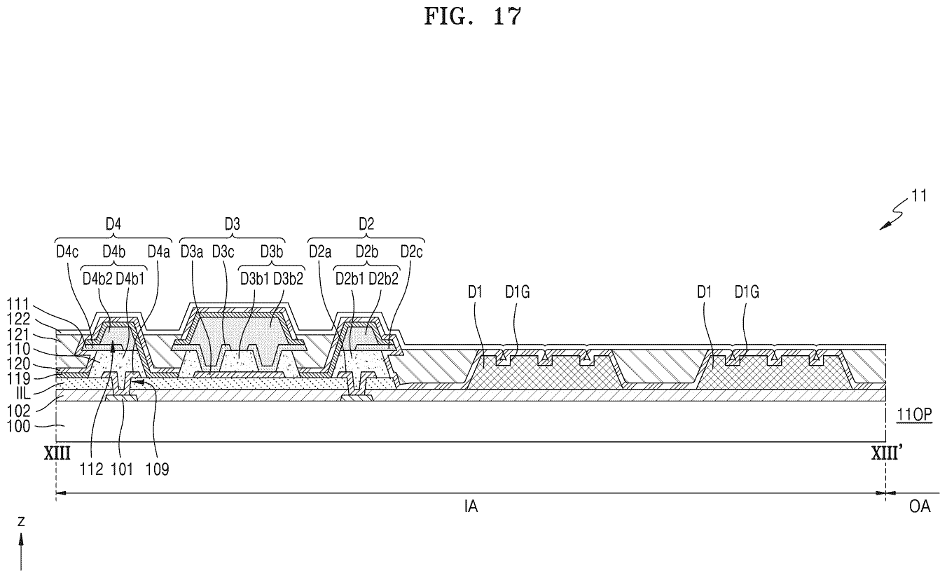

FIG. 17 is a cross-sectional view of a display panel according to an embodiment. FIG. 17 may be a cross-sectional view of the display panel, for example, taken along the line XIII-XIII′ in FIG. 13.

Referring to FIG. 17, the organic encapsulation layer 121 may be disposed between the first dams D1 that are adjacent to each other. In an embodiment, the organic encapsulation layer 121 may be disposed between the first dam D1 and the second dam D2. In an embodiment, in an area between the adjacent first dams D1, the first inorganic encapsulation layer 120 and the second inorganic encapsulation layer 122 may be spaced apart from each other by the organic encapsulation layer 121 disposed therebetween. In an embodiment, in an area overlapping with the first dam D1, the organic encapsulation layer 121 may not be disposed between the first inorganic encapsulation layer 120 and the second inorganic encapsulation layer 122. In an embodiment, in an area overlapping with the first dam D1, the first inorganic encapsulation layer 120 and the second inorganic encapsulation layer 122 may come into direct contact with each other.

The organic encapsulation layer 121 disposed in the area between the adjacent first dams D1 may contribute to preventing (or at least reducing) the gap described above.

FIGS. 18A through 18G are cross-sectional views illustrating various processes of a method of manufacturing a display panel according to some embodiments.

Referring to FIG. 18A, the first insulating layer 102, the inorganic insulating layer IIL, the fourth conductive layer 109, the fifth insulating layer 110, the fifth conductive layer 111, the sixth insulating layer 112, and the second electrode 119 may be formed on the substrate 100. In a current stage of a process, the second dam D2, the third dam D3, and the fourth dam D4 may be formed in the intermediate area IA. A first inner organic portion IDa and a second inner organic portion IDb may be formed in the opening area OA. The second inner organic portion IDb may be disposed on the first inner organic portion IDa, and may cover the first inner organic portion IDa. In an embodiment, the second inner organic portion IDb may cover an upper surface and a side surface of the first inner organic portion IDa.

In an embodiment, the first inner organic portion IDa may include a same material as the sixth insulating layer 112. In an embodiment, the first inner organic portion IDa may be formed in a same process as the sixth insulating layer 112. In an embodiment, the first inner organic portion IDa may be considered as a portion of the sixth insulating layer 112.

In an embodiment, referring to FIG. 12 together with FIG. 18A, the second inner organic portion IDb may include a same material as the pixel-defining layer 114. In an embodiment, the second inner organic portion IDb may be formed in a same process as that of the pixel-defining layer 114. In an embodiment, the second inner organic portion IDb may be considered as a portion of the pixel-defining layer 114.

As described above with reference to FIG. 14, when the first dam D1 is formed in a same process as that of the fifth insulating layer 110, the sixth insulating layer 112, or the pixel-defining layer 114, the first dam D1 may be formed on the first insulating layer 102 in the current stage of the process. Below, for convenience of illustration, the first dam D1 is may described as being formed on a separate organic insulating layer (e.g., the spacer layer as described above).

Referring to FIG. 18B, the first dam D1 may be formed in the intermediate area IA and the opening area OA.

In an embodiment, the first dam D1 may be formed as a portion of the organic insulating layer (e.g., the spacer layer) as described above. The plurality of first dams D1 may be disposed on the substrate 100, some of the plurality of first dams D1 may be disposed within the intermediate area IA, and others may be disposed within the opening area OA. The plurality of first dams D1 may be spaced apart from each other. Although FIG. 18B shows three first dams D1, the present disclosure is not limited to a specific number of first dams D1. In addition, although FIG. 18B shows an embodiment in which two first dams D1 are disposed in the intermediate area IA, and one first dam D1 is disposed in the opening area OA, the present disclosure is not limited to a specific number of first dams D1 that are disposed within a specific area. In an embodiment, two first dams D1 may be disposed in the intermediate area IA and two first dams D1 may be disposed in the opening area OA. In an embodiment, three first dams D1 may be disposed in the intermediate area IA and one first dam D1 may be disposed in the opening area OA. In the current stage of the process, upper surfaces of the first dams D1 may be flat or substantially flat. In other words, the current stage of the process may be a stage prior to a formation of the first groove D1G (e.g., see FIG. 14) in the first dams D1.

An inner dam ID may be formed in the opening area OA. The inner dam ID may include the first inner organic portion IDa, the second inner organic portion IDb, and a third inner organic portion IDc. In an embodiment, the third inner organic portion IDc may be disposed on the second inner organic portion IDb. In an embodiment, the third inner organic portion IDc may cover an upper surface and a side surface of the second inner organic portion IDb. In an embodiment, it may be understood that the inner dam ID is completed by forming the third inner organic portion IDc.

In an embodiment, the third inner organic portion IDc may include a same material as that of the first dam D1, and may be formed as a portion of a same layer (e.g., the spacer layer described above) as that of the first dam D1. In an embodiment, the plurality of first dams D1 and the third inner organic portion IDc may be formed concurrently (e.g., simultaneously or substantially simultaneously) with each other. In an embodiment, the first inner organic portion IDa, the second inner organic portion IDb, and the third inner organic portion IDc may be included, such that the inner dam ID is formed thicker than the first dam D1.

Referring to FIG. 18C, the first groove D1G and a second groove IDG may be formed.

In an embodiment, the first groove D1G may be formed in the first dam D1. In an embodiment, the second groove IDG may be formed in the inner dam ID, for example, such as in the third inner organic portion IDc of the inner dam ID. In an embodiment, the first groove D1G and the second groove IDG may be formed concurrently (e.g., simultaneously or substantially simultaneously) with each other. In an embodiment, a process of forming the first groove D1G and the second groove IDG may include etching (e.g., dry etching). In an embodiment, a cross-sectional shape of the first groove D1G and a cross-sectional shape of the second groove IDG may be the same or substantially the same as each other. In other words, grooves having the same or substantially the same cross-sectional shape as each other may be formed in the first dam D1 and the inner dam ID.

Referring to FIG. 18D, the first inorganic encapsulation layer 120 may be formed.

In an embodiment, a process of forming the first inorganic encapsulation layer 120 may include chemical vapor deposition (CVD). In an embodiment, the first inorganic encapsulation layer 120 may cover the first dam D1, the second dam D2, the third dam D3, the fourth dam D4, and the inner dam ID. In an embodiment, the first inorganic encapsulation layer 120 may extend integrally and cover the plurality of first dams D1, the second dam D2, and the inner dam ID. In an embodiment, the first inorganic encapsulation layer 120 may extend integrally and cover an upper surface, a side surface, and a lower surface of the first-second metal portion D2c protruding beyond a side surface of the first organic portion D2b. In an embodiment, the first inorganic encapsulation layer 120 may cover a protruding portion of the first-second metal portion D2c, and may integrally extend and cover all of a side surface of the first-first organic portion D2b1, a side surface of the inorganic insulating layer IIL, and an upper surface of the first insulating layer 102 located under the first-second metal portion D2c.

In an embodiment, the first inorganic encapsulation layer 120 may be disposed on the first dam D1, as in the structure described above with reference to FIG. 15.

The relationship between the first dam D1 and the first inorganic encapsulation layer 120 described above with reference to FIG. 15 may be equally (or at least similarly) applied between the inner dam ID and the first inorganic encapsulation layer 120. In an embodiment, because the second groove IDG having a shape similar to a shape of the first groove D1G may be defined in the inner dam ID, the first inorganic encapsulation layer 120 may be disposed on the inner dam ID in a similar manner as that of the first inorganic encapsulation layer 120 disposed on the first dam D1. In an embodiment, portions (e.g., a third portion and a fourth portion) of the first inorganic encapsulation layer 120 overlapping with edges of the third inner organic portion IDc defining the second groove IDG may come into contact with each other in an area overlapping with the second groove IDG.

Referring to FIG. 18E, the organic encapsulation layer 121 and the second inorganic encapsulation layer 122 may be formed.

The organic encapsulation layer 121 may be disposed on the first inorganic encapsulation layer 120, and the second inorganic encapsulation layer 122 may be disposed on the organic encapsulation layer 121. The second inorganic encapsulation layer 122 may cover the organic encapsulation layer 121 and the first inorganic encapsulation layer 120 entirely. In an embodiment, a process of forming the second inorganic encapsulation layer 122 may include CVD.

In some embodiments, the organic encapsulation layer 121 may be disposed between the plurality of first dams D1, similar to that of the embodiment described above with reference to FIG. 17. In an embodiment, the organic encapsulation layer 121 may be disposed between two adjacent ones of the plurality of first dams D1. In an embodiment, within the opening area OA, the organic encapsulation layer 121 may be disposed between the first dam D1 and the inner dam ID.

Referring to FIG. 18F, the substrate 100 may be cut along a boundary between the opening area OA and the intermediate area IA, for example, such as along a cutting line CT corresponding to the boundary.

In an embodiment, the first insulating layer 102, the first inorganic encapsulation layer 120, and the second inorganic encapsulation layer 122 may be cut together with the substrate 100. In an embodiment, the cutting may include a laser cutting.

Referring to FIGS. 18F and 18G, the elements disposed within the opening area OA may be removed.

In an embodiment, a portion of the substrate 100 corresponding to the opening area OA may be removed. In an embodiment, portions of the first insulating layer 102, the first inorganic encapsulation layer 120, and the second inorganic encapsulation layer 122 corresponding to the opening area OA may be removed. In an embodiment, the first dam D1 disposed within the opening area OA may be removed. In an embodiment, the inner dam ID, for example, such as the first inner organic portion IDa, the second inner organic portion IDb, and the third inner organic portion IDc, may be removed. Because the elements are removed, the transmissive opening 11OP overlapping with the opening area OA may be formed.

In the cutting process and the removing process described above with reference to FIGS. 18F and 18G, a delamination may occur between the first inorganic encapsulation layer 120 and the first insulating layer 102 (e.g., due to a lack of an adhesive force). The delamination may cause a gap between the first inorganic encapsulation layer 120 and the second inorganic encapsulation layer 122.

The gap may be caused especially by residual stress remaining in the first inorganic encapsulation layer 120 after the first inorganic encapsulation layer 120 is formed. In an embodiment, when the first inorganic encapsulation layer 120 is cut along the cutting line CT, an expansion may occur in the first inorganic encapsulation layer 120 due to the residual stress. Because the first inorganic encapsulation layer 120 is covered by the second inorganic encapsulation layer 122, the expansion may occur generally in a horizontal direction, for example, such as in a direction perpendicular to or substantially perpendicular to the z-axis direction. The expansion may generate a stress in the first inorganic encapsulation layer 120 toward a location where the cutting takes place, for example, such as toward the cutting line CT. The expansion and the stress may induce the first inorganic encapsulation layer 120 to be delaminated from the layer disposed thereunder, for example, such as from the first insulating layer 102. Accordingly, the first inorganic encapsulation layer 120 may be delaminated from the first insulating layer 102, and a gap of the first inorganic encapsulation layer 120 may spread in a horizontal direction, for example, such as in the direction perpendicular to or substantially perpendicular to the z-axis direction. In this case, the spreading of the gap may denote that an area where the first inorganic encapsulation layer 120 is delaminated (or spaced apart) from the first insulating layer 102 increases.

When the gap of the first inorganic encapsulation layer 120 continuous to spread and reaches the second dam D2, a stress may be concentrated on a portion of the first inorganic encapsulation layer 120 located under the first-second metal portion D2c of the second dam D2, for example, such as on a portion adjacent to an edge of the inorganic insulating layer IIL. The concentration of the stress may lead to cracking of the first inorganic encapsulation layer 120 (and the second inorganic encapsulation layer 122) in that area.

A structure of the first dam D1 (and similarly, a structure of the inner dam ID) may prevent (or at least reduce) the delamination (or the gap) of the first inorganic encapsulation layer 120 as described above. Referring to FIG. 15 together with FIGS. 18F and 18G, a portion of the first inorganic encapsulation layer 120 may be disposed within the first groove D1G of the first dam D1, so that the first inorganic encapsulation layer 120 may have portions facing and in contact with each other on the first groove D1G, for example, such as the first portion 1201 and the second portion 1202. When the horizontal direction (e.g., the direction perpendicular to or substantially perpendicular to the z-axis direction) expansion and stress of the first inorganic encapsulation layer 120 occurs, the first portion 1201 and the second portion 1202 may push against each other while being in contact with each other. For example, the first portion 1201 may expand in a direction toward the opening area OA, and the second portion 1202 may expand in a direction opposite to the direction toward the opening area OA. The expansion forces (e.g., the stresses) of the first portion 1201 and the second portion 1202 may be opposite to each other in a direction, and thus, may cancel each other out. As such, a stress formed within the first inorganic encapsulation layer 120 may be at least partially relieved, and an expansion (e.g., in the horizontal direction) of the first inorganic encapsulation layer 120 may be prevented (or at least reduced). In addition, by applying a force that pushes the first portion 1201 and the second portion 1202 against each other, the first portion 1201 may anchor itself to the first groove D1G of the first dam D1, which may contribute to preventing (or at least reducing) the delamination (or the gap) of the first inorganic encapsulation layer 120.

FIGS. 14, 18F, and 18G show embodiments in which the delamination and gap of the first inorganic encapsulation layer 120 are completely prevented during the cutting through the structure of the first dam D1 and the first inorganic encapsulation layer 120. However, the present disclosure is not limited thereto. Referring to FIG. 16, a partial delamination and gap of the first inorganic encapsulation layer 120 may occur during a cutting process, but the structure of the first dam D1 described above according to one or more embodiments may be utilized to reduce (or minimize) the occurrence and spreading of the delamination and gap. In other words, the structure of the first dam D1 and the first inorganic encapsulation layer 120 of one or more embodiments described above may prevent (or at least reduce) the delamination and gap of the first inorganic encapsulation layer 120, and may prevent (or at least reduce) the propagation of the delamination and gap, which may inevitably occur.

In an embodiment, such prevention (or at least reduction) may also be achieved through a relationship between the first inorganic encapsulation layer 120 and the inner dam ID.

According to some embodiments of the present disclosure as described above, a delamination between some layers (e.g., an inorganic encapsulation layer and an inorganic insulating layer) on a substrate and a gap of a layer (e.g., an inorganic encapsulation layer) during a cutting and removing process for forming an opening in a display panel may be prevented (or at least reduced). The preventing (or at least reducing) such delamination and gap may be achieved through the dam structure and inorganic encapsulation layer structure as described above.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a substrate comprising an opening area, an intermediate area at least partially surrounding around the opening area, and a display area at least partially surrounding around the intermediate area;
a light-emitting diode in the display area;
a first dam in the intermediate area, and having at least one first groove defined in an upper surface of the first dam; and
a second dam between the first dam and the display area, the second dam comprising:
an organic material portion; and
a metal portion within the organic material portion, and having a portion protruding beyond a side surface of the organic material portion.

2. The display panel of claim 1, further comprising an inorganic encapsulation layer on the first dam and the second dam.

3. The display panel of claim 2, wherein the inorganic encapsulation layer comprises a first portion and a second portion overlapping with a first edge and second edge, respectively, of the first dam defining the at least one first groove, and the first portion and the second portion of the inorganic encapsulation layer are in contact with each other.

4. The display panel of claim 2, wherein the inorganic encapsulation layer integrally extends and covers an upper surface, a side surface, and a lower surface of the metal portion protruding beyond the side surface of the organic material portion.

5. The display panel of claim 2, wherein a portion of a lower surface of the inorganic encapsulation layer located on the first dam is spaced from a portion of an upper surface of the first dam.

6. The display panel of claim 2, wherein the first dam comprises a plurality of first dams, and
the display panel further comprises, on the inorganic encapsulation layer, an organic encapsulation layer having at least a portion located between two adjacent first dams of the plurality of first dams.

7. The display panel of claim 2, wherein a width of the first groove of the first dam is about 1.5 to about 2 times a thickness of the inorganic encapsulation layer on the first dam.

8. The display panel of claim 1, wherein, in a plan view, the first dam surrounds around the opening area.

9. The display panel of claim 1, wherein an opening overlapping with the opening area is defined in the substrate.

10. A method of manufacturing a display panel, the method comprising:
preparing a substrate in which an opening area, an intermediate area at least partially surrounding around the opening area, and a display area at least partially surrounding around the intermediate area are defined;
placing, in the intermediate area, a first dam having at least one first groove defined in an upper surface of the first dam;
placing an inorganic encapsulation layer on the first dam, a first portion and a second portion of the inorganic encapsulation layer overlapping with a first edge and a second edge, respectively, of the first dam defining the at least one first groove being in contact with each other in an area overlapping with the at least one first groove; and
cutting the substrate along a boundary between the intermediate area and the opening area.

11. The method of claim 10, further comprising placing, between the first dam and the display area, a second dam comprising:
an organic material portion; and
a metal portion disposed within the organic material portion, and protruding beyond a side surface of the organic material portion.

12. The method of claim 11, wherein the inorganic encapsulation layer is disposed on the second dam, and integrally extends and covers an upper surface, a side surface, and a lower surface of a portion of the metal portion protruding beyond the side surface of the organic material portion of the second dam.

13. The method of claim 10, wherein, in the cutting of the substrate, a portion of a lower surface of the inorganic encapsulation layer located on the first dam is spaced from a portion of an upper surface of the first dam.

14. The method of claim 10, wherein the first dam comprises a plurality of first dams, and
wherein the method further comprises placing an organic encapsulation layer on the inorganic encapsulation layer, at least a portion of the organic encapsulation layer being located between two adjacent first dams of the plurality of first dams.

15. The method of claim 10, further comprising placing, in the opening area, an inner dam having at least one second groove defined in an upper surface of the inner dam.

16. The method of claim 15, wherein a cross-sectional shape of the at least one first groove of the first dam and a cross-sectional shape of the at least one second groove of the inner dam are same as each other.

17. The method of claim 15, wherein the inorganic encapsulation layer is disposed on the inner dam, and comprises a third portion and a fourth portion overlapping with a first edge and a second edge, respectively, of the inner dam defining the at least one second groove, and the third portion and the fourth portion of the inorganic encapsulation layer are in contact with each other in an area overlapping with the at least one second groove.

18. The method of claim 15, further comprising removing a portion of the substrate corresponding to the opening area together with the inner dam.

19. The method of claim 10, wherein the inorganic encapsulation layer extends across the display area, the intermediate area, and the opening area, and the inorganic encapsulation layer is cut together with the substrate in the cutting of the substrate.

20. An electronic device comprising:
a display panel; and
a processor configured to drive the display panel,
wherein the display panel comprises:
a substrate comprising an opening area, an intermediate area at least partially surrounding around the opening area, and a display area at least partially surrounding around the intermediate area;
a light-emitting diode in the display area;
a first dam in the intermediate area, and having at least one first groove defined in an upper surface of the first dam; and
an inorganic encapsulation layer covering the light-emitting diode and the first dam,
wherein the inorganic encapsulation layer comprises a first portion and a second portion overlapping with a first edge and second edge, respectively, of the first dam defining the at least one first groove, and
wherein the first portion and the second portion of the inorganic encapsulation layer are in contact with each other.
